(19) United States
(12) Patent Application Publication
(10) Pub. No.: US 2025/0233065 A1
(43) Pub. Date: Jul. 17, 2025

(54) THREE-DIMENTIONAL SEMICONDUCTOR DEVICE

(71) Applicant: SK hynix Inc., Icheon-si (KR)

(72) Inventor: Sung Lae OH, Icheon-si (KR)

(21) Appl. No.: 19/170,687

(22) Filed: Apr. 4, 2025

Related U.S. Application Data
(63) Continuation-in-part of application No. 18/505,998, filed on Nov. 9, 2023, now Pat. No. 12,293,967.
Application No. 18/505,998 is a continuation of application No. 17/467,678, filed on Sep. 7, 2021, now Pat. No. 11,848,266.

(30) Foreign Application Priority Data
Apr. 6, 2021 (KR) 10-2021-0044510

(51) Int. Cl. H01L 23/522; H01L 21/768; H01L 23/528; H10B 69/00

(52) U.S. Cl. CPC H01L 23/5226; H01L 21/76816; H01L 23/5283; H10B 69/00

(57) ABSTRACT

A three-dimensional semiconductor device includes a bottom word line stack with a top via plug region and a bottom via plug region, a top word line stack over the bottom word line stack; top via plugs disposed in the top via plug region; and bottom via plugs disposed in the bottom via plug region. The bottom via plugs include upper bottom via plugs extending vertically and completely through the top word line stack; and lower bottom via plugs extending vertically and partially through the bottom word line stack. An interface between the bottom word line stack and the top word line stack and interfaces of the lower bottom via plugs and the upper bottom via plugs are located at a same level. A horizontal width of an upper end of each of the lower bottom via plugs is greater than a horizontal width of a lower end of each of the upper bottom via plugs.

### CROSS-REFERENCE TO RELATED APPLICATIONS

This application is a continuation-in-part application of U.S. patent application Ser. No. 18/505,998, filed on Nov. 9, 2023, which is a continuation application of U.S. patent application Ser. No. 17/467,678, filed on Sep. 7, 2021, now issued as U.S. Pat. No. 11,848,266 on Dec. 19, 2023, which claims priority under 35 U.S.C. § 119(a) to Korean Patent Application No. 10-2021-0044510 filed on Apr. 6, 2021, which are incorporated herein by reference in their entirety.

### BACKGROUND

### 1. Field

The present disclosure relates to a three-dimensional semiconductor device including a plurality of via plugs, having different vertical lengths, that are arranged in a zigzag pattern.

### 2. Description of the Related Art

Recently, the increases in capacity and miniaturization of the three-dimensional semiconductor devices are ongoing. As a result, signal delay and voltage drop phenomena due to stacking of three-dimensional semiconductor devices are emerging as particular problems.

### SUMMARY

Embodiments of the present disclosure are to provide a three-dimensional semiconductor device including a via plug region disposed between cell regions and a method for fabricating the same.

Embodiments of the present disclosure are to provide a three-dimensional semiconductor device in which cells in cell regions share the same word line and a method for fabricating the same.

Embodiments of the present disclosure are to provide a three-dimensional semiconductor device having via plugs arranged in a zigzag pattern in a via plug region and a method for fabricating the same.

Embodiments of the present disclosure are to provide a three-dimensional semiconductor device including via plugs having different diameters and a method for fabricating the same.

According to an embodiment of the present disclosure, a three-dimensional semiconductor device may comprise a first cell region, a second cell region, and a via plug region disposed between the first cell region and the second cell region; a word line stack disposed in the first cell region, the via plug region, and the second cell region, the word line stack including a plurality of word lines and a plurality of interlayer insulating layers which are alternately stacked; and a plurality of via plugs exclusively connected to the plurality of the word lines, respectively, by vertically penetrating through the word line stack in the via plug region. The via plugs may be arranged in a zigzag pattern in a row direction from a top view. The diameters of the via plugs may increase in the row direction.

According to an embodiment of the present disclosure, a three-dimensional semiconductor device may comprise a first cell region, a second cell region, and a via plug region disposed between the first cell region and the second cell region; a word line stack disposed in the first cell region, the via plug region, and the second cell region, the word line stack including a plurality of word lines and a plurality of interlayer insulating layers that are alternately stacked; and a plurality of via plugs exclusively connected to the plurality of the word lines, respectively, by vertically penetrating through the word line stack. All of the word lines may laterally extend from the first cell region across the via plug region to the second cell region. The plurality of via plugs may have an arrangement of a zigzag pattern in a row direction from a top view.

According to an embodiment of the present disclosure, a three-dimensional semiconductor device may comprise a first cell region and a via plug region; a word line stack disposed in the first cell region and the via plug region, the word line stack including a plurality of word lines and a plurality of interlayer insulating layers which are alternately stacked; and a plurality of via plugs exclusively connected to the plurality of the word lines, respectively, by vertically penetrating the word line stack in the via plug region. All of the word lines may laterally extend from the first cell region to the via plug region. Diameters of the plurality of via plugs may increase in a row direction from a top view.

According to an embodiment of the present disclosure, a method of manufacturing a three-dimensional semiconductor device includes forming a bottom insulating layer stack having a top via plug region and a bottom via plug region, forming lower bottom via hole patterns vertically extending through the bottom insulating layer stack in the bottom via plug region, forming sacrificial via plugs by filling the lower bottom via hole patterns with a filling material, forming a top insulating layer stack over the bottom insulating layer stack, forming top via hole patterns extending vertically through the top insulating layer stack in the top via plug region, forming upper bottom via hole patterns vertically passing through the top insulating layer stack and vertically aligned with the sacrificial via plugs in the bottom via plug region, respectively, removing the filling material of the sacrificial via plug in the lower bottom via hole patterns, and filling the top via hole patterns, the lower bottom via hole patterns, and the upper bottom via hole patterns with a conductor to form top via plugs, lower bottom via plugs, and upper bottom via plugs.

According to an embodiment of the present disclosure, a method of manufacturing a three-dimensional semiconductor includes forming a bottom insulating layer stack having a top via plug region, a shallow bottom via plug region, and a deep bottom via plug region, forming lower deep bottom via hole patterns extending vertically through the bottom insulating layer stack in the deep bottom via plug region, forming deep sacrificial via plugs by filling the lower deep bottom via hole patterns with a filling material, forming a top insulating layer stack over the bottom insulating layer stack, forming top via hole patterns extending vertically through the top insulating layer stack in the top via plug region, forming upper deep bottom via hole patterns extending vertically through the top insulating layer stack and vertically aligned with the deep sacrificial via plugs in the deep bottom via plug region, removing the filling material of the deep sacrificial via plugs in the lower deep bottom via hole patterns, and filling the top via hole patterns, the lower deep bottom via hole patterns, and the upper deep bottom via hole patterns with a conductor to form top via plugs, lower deep bottom via plugs, and upper deep bottom via plugs.

According to an embodiment of the present disclosure, a three-dimensional semiconductor device includes a lower layer with a top via plug region, a shallow bottom via plug region, and a deep bottom via plug region; a bottom word line stack stacked over the lower layer; a top word line stack stacked over the bottom word line stack, wherein the top word line stack includes top word lines and top interlayer insulating layers alternately stacked; top via plugs extending vertically through the top word line stack in the top via plug region; upper deep bottom via plugs extending vertically and completely through the top word line stack; and lower deep bottom via plugs extending vertically and partially through the bottom word line stack. The bottom word line stack includes a bottom lower insulating layer, a bottom upper insulating layer, bottom word lines and the bottom interlayer insulating layers alternately stacked between the bottom lower insulating layer and bottom upper insulating layers. The top word line stack includes a top lower insulating layer, top upper insulating layer, top word lines and top interlayer insulating layers alternately stacked between the top lower insulating layer and the top upper insulating layer. The top via plugs are electrically connected to the top word lines, respectively. The upper deep bottom via plugs and the lower deep bottom via plugs are vertically aligned with each other, respectively. A lower end of each of the of the lower deep bottom via plugs is electrically connected to each of the bottom word lines, respectively. A horizontal width of an upper end of each of the lower deep bottom via plugs is greater than a horizontal width of a lower end of each of the upper deep bottom via plugs.

According to an embodiment of the present disclosure, a three-dimensional semiconductor device includes a bottom word line stack with a top via plug region and a bottom via plug region, and a top word line stack over the bottom word line stack; top via plugs disposed in the top via plug region; and bottom via plugs disposed in the bottom via plug region. The bottom via plugs include upper bottom via plugs extending vertically and completely through the top word line stack; and lower bottom via plugs extending vertically and partially through the bottom word line stack. An interface between the bottom word line stack and the top word line stack and interfaces of the lower bottom via plugs and the upper bottom via plugs are located at a same level. A horizontal width of an upper end of each of the lower bottom via plugs is greater than a horizontal width of a lower end of each of the upper bottom via plugs at the interface between the bottom word line stack and the top word line stack.

Cells in two cell regions may be controlled with a single word line control circuit since a three-dimensional semiconductor device according to the embodiments of the present disclosure includes a via plug region disposed between cell regions.

In a three-dimensional semiconductor device according to the embodiments of the present disclosure, the area occupied by the device may be reduced because the cells in a cell region share the same word line.

In a three-dimensional semiconductor device according to the embodiments of the present disclosure, the area occupied by the device may be reduced because the via plugs are arranged in a zigzag pattern within the via plug region.

Accordingly, the productivity of the device can be increased and the unit cost can be lowered.

### BRIEF DESCRIPTION OF THE DRAWINGS

FIGS. 1A and 1B are layouts illustrating cell regions and via plug regions of three-dimensional semiconductor devices according to embodiments of the present disclosure.

FIG. 1C is a layout illustrating an enlarged view of region A of FIG. 1A.

FIG. 1D is a layout illustrating the diameters of a plurality of via plugs disposed in one of a plurality of sites of FIG. 1C.

FIG. 1E is a top view illustrating average diameters of via plugs disposed in a plurality of sites of FIG. 1C.

FIG. 2 is a longitudinal cross-sectional view of a three-dimensional semiconductor device according to an embodiment of the present disclosure.

FIGS. 3A to 18 are diagrams illustrating a method of fabricating a three-dimensional semiconductor device according to an embodiment of the present disclosure.

FIGS. 19A and 19B are block diagrams illustrating a configuration of memory systems according to embodiments of the present disclosure.

FIGS. 19C and 19D are block diagrams illustrating a configuration of computing systems according to embodiments of the present disclosure.

FIGS. 20A to 201, 21A to 21D, and 22A to 22H are diagrams illustrating methods of forming three-dimensional semiconductor devices according to embodiments of the present disclosure.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating the materials associated with the areas.

When one element is identified as “connected” or “coupled” to another element, the elements may be connected or coupled directly or through one or more intervening elements. When two elements are identified as “directly connected” or “directly coupled,” one element is directly connected or directly coupled to the other element without any intervening element.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise to limit scope. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

Concepts are disclosed in conjunction with examples and embodiments as described hereunder. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the descriptions below. All changes within the meaning and range of equivalency of the claims are included within their scope.

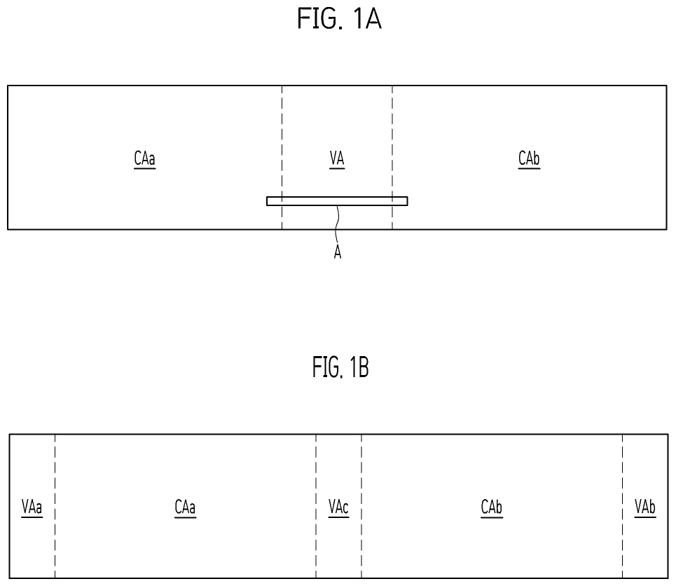

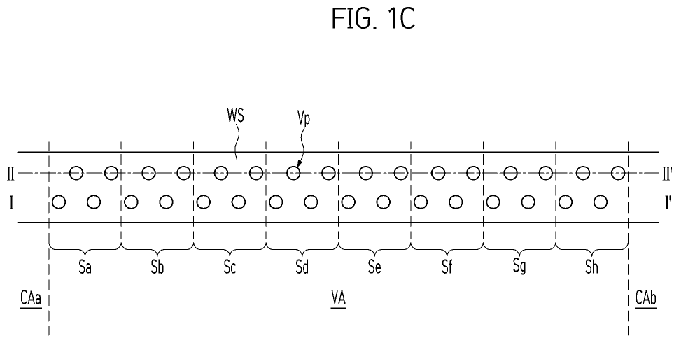

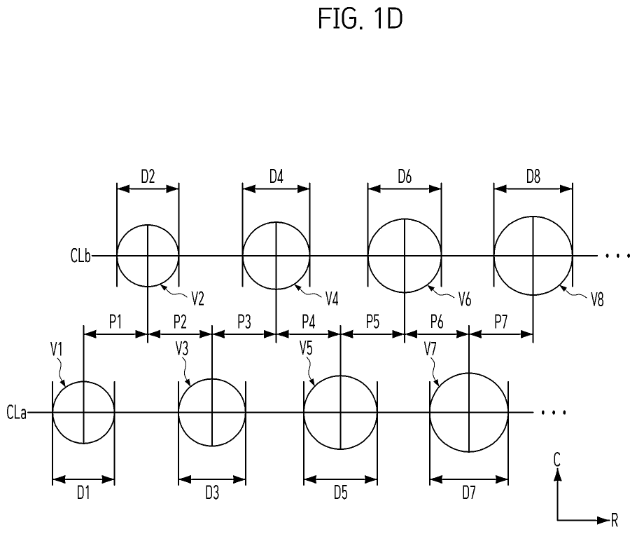

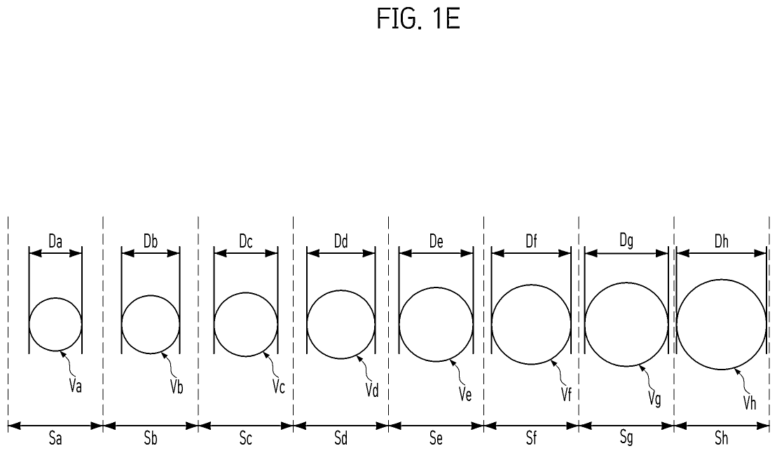

FIGS. 1A and 1B are layouts illustrating cell regions CAa and CAb and via plug regions VA of three-dimensional semiconductor devices according to embodiments of the present disclosure. Referring to FIG. 1A, a via plug region VA may be disposed between cell regions CAa and CAb. The cell regions CAa and CAb may include memory cells. The cell regions CAa and CAb may include a first cell region CAa located on one side of the via plug region VA and a second cell region CAb located on the other side of the via plug region VA. The via plug region VA may include via plugs to be connected to a decoding circuit controlling word lines. The cell regions CAa and CAb and the via plug region VA may be disposed or arranged side-by-side in a first direction.

Referring to FIG. 1B, via plug regions VAa, VAb, and VAc may be distributed to be adjacent to side edges of the cell regions CAa and CAb in the first direction. For example, the via plug regions VAa, VAb, and VAc may include a first via plug region VAa adjacent to a left-side edge of the first cell region CAa, a second via plug region VAb adjacent to a right-side edge of the second cell region CAb, and a third via plug region VAc between the first cell region CAa and the second cell region CAb. The memory cells in each of the cell regions CAa and CAb may be connected to one of the via plug regions VAa, VAb, and VAc located adjacent to the cell regions.

FIG. 1C is a layout illustrating an enlarged view of region A of FIG. 1A. Referring to FIG. 1C, the via plug region VA may be divided into a plurality of sites Sa to Sh arranged in a row direction R. The three-dimensional semiconductor device may include a plurality of via plugs Vp disposed in the plurality of sites Sa to Sh in the via plug region VA. The same number of via plugs Vp may be disposed in each of the sites Sa to Sh. The via plugs Vp may be disposed to vertically penetrate through a word line stack WS, which extends in the row direction from the first cell region CAa to the second cell region CAb across the via plug region VA. The via plugs Vp may be alternately arranged in a zigzag pattern in the row direction. There may be more or fewer of the plurality of sites Sa to Sh than shown. For example, the number of the sites Sa to Sh may be seven or less, or nine or more. In the drawing, each of the sites Sa to Sh is shown to have four via plugs Vp, but the present disclosure is not limited thereto. For example, each of the sites Sa to Sh may include five or more via plugs Vp, or may include less than four via plugs Vp.

FIG. 1D is a layout illustrating diameters D1 to D8 of a plurality of via plugs V1 to V8 disposed in one of the plurality of sites Sa to Sh illustrated in FIG. 1C. Referring to FIG. 1D, the diameters D1 to D8 of first to eighth via plugs V1 to V8 disposed in each of the sites Sa to Sh may gradually increase in the row direction R. In an embodiment, eight via plugs V1 to V8 may be placed in each of the plurality of sites Sa to Sh and may be arranged in a zigzag pattern. For example, the eight via plugs V1 to V8 may be arranged in two rows illustrated by lower center line CLa and upper center line CLb. The two rows of via plugs V1 to V8 may be offset relative to each other due to the zigzag pattern. Two adjacent diameters from among the diameters D1 to D8 of the via plugs V1 to V8 may decrease in size in the row direction R, but the diameters D1 to D8 of the via plugs V1 to V8 may increase overall in the row direction R (an increasing trend). In the zigzag pattern, the centers of the lower via plugs V1, V3, V5, and V7 may be aligned with the lower center line CLa, and the centers of the upper via plugs V2, V4, V6, and V8 may be aligned with the upper center line CLb. The row direction pitches P1 to P7 or the row direction gaps between the centers of the via plugs V1 to V8 may be the same in the row direction R. In some parts or some embodiments, the diameters D1 to D8 of the via plugs V1 to V8 may be larger than the row direction pitches P1 to P7. That is, some of the via plugs V1 to V8 may partially overlap with each other in the column direction C, as illustrated in FIG. 1D. In another embodiment, the row direction pitches P1 to P7 may increase in the row direction R. While some of the adjacent row direction pitches in the row direction R may decrease, the pitches P1 to P7 overall may increase in the row direction R.

FIG. 1E is a top view illustrating average diameters Da to Dh of via plugs Va to Vh disposed in a plurality of sites Sa to Sh. With further reference to FIG. 1C, in an embodiment, the average diameters Da to Dh of the via plugs Va to Vh may increase in the row direction R, i.e., Da<Db<Dc<Dd<De<Df<Dg<Dh. In another embodiment, sites Sa to Sh may be randomly arranged. In this case, the average diameters Da to Dh of the via plugs Va to Vh may be randomly arranged without an increasing trend in diameter size in any direction. For example, the average diameters Da to Dh of the via plugs Va to Vh may be slightly different from each other. (Da≠Db≠Dc≠Dd≠De≠Df≠Dg≠Dh). In another embodiment, some of the via plugs Va to Vh may have the same diameters while some others may have different diameters, as will be described below with reference to other drawings of the present disclosure.

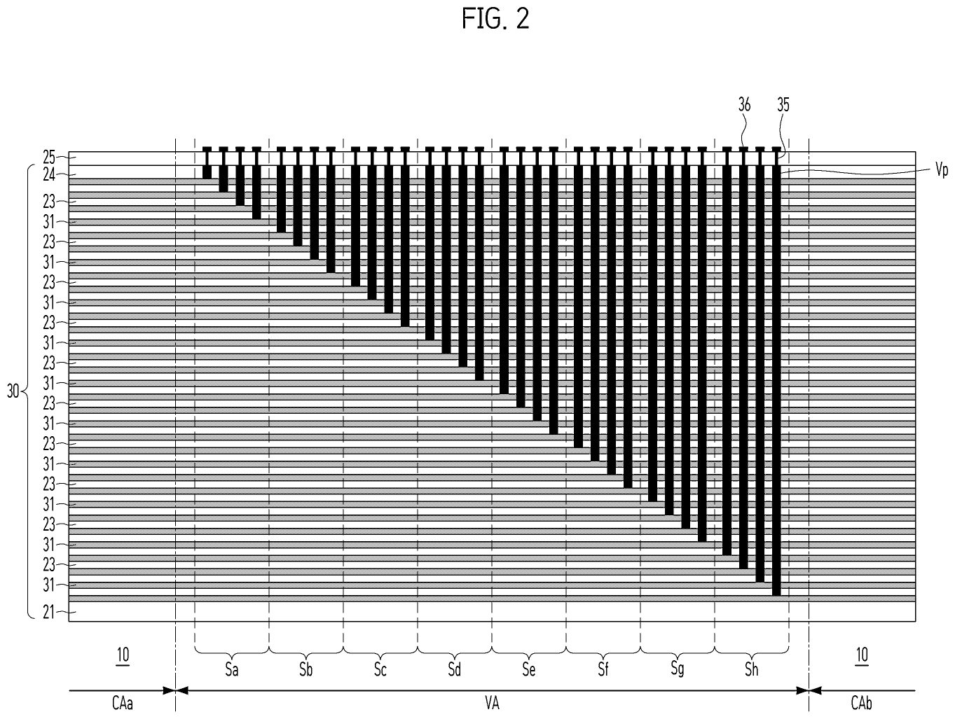

FIG. 2 is a longitudinal cross-sectional view of a three-dimensional semiconductor device according to an embodiment of the present disclosure. In FIG. 2, longitudinal cross-sectional views taken along lines I-I′ and II-II′ of FIG. 1C are overlapped. According to FIGS. 1A to 1E and FIG. 2, a three-dimensional semiconductor device according to an embodiment of the present disclosure may include a first cell region CAa, a second cell region CAb, a via plug region VA disposed between the first and second cell regions CAa and CAb, a word line stack 30, and via plugs Vp. The word line stack 30 may extend across all of the first cell region CAa, the via plug region VA, and the second cell region CAb in a row direction. The word line stack 30 may include a lower insulating layer 21 stacked on a lower layer 10, as well as a plurality of word lines 31 and a plurality of interlayer insulating layers 23 alternately stacked with each other, and an upper insulating layer 24.

Each of the first cell region CAa and the second cell region CAb may include a plurality of vertical channel structures (not shown) vertically penetrating the word line stack 30 and a plurality of memory cells. That is, each of the word lines 31 may be simultaneously turned on and turned off in the first cell region CAa and the second cell region CAb. For example, the word lines 31 may include a metal such as tungsten (W).

The word lines 31 of the word line stack 30 may laterally extend from the first cell region CAa to the second cell region CAb across the via plug region VA. That is, the word lines 31 may extend to the two cell regions CAa and CAb without being cut or disconnected in the via plug region VA. Each of the word lines 31 may be commonly connected to a plurality of memory cells disposed in the first cell region CAa and the second cell region CAb. Accordingly, memory cells in the first and the second cell regions CAa and CAb may share the word lines 31, and the word lines 31 may simultaneously turn-on and turn-off the memory cells in the first and second cell regions CAa and CAb. Referring further to FIG. 1A, an operation time delay and a difference in supply power, due to resistance and capacitance of the cells in the first and second cell regions CAa and CAb, may be minimized because the memory cells located in the first and second cell regions CAa and CAb are simultaneously turned on and turned off by the via plugs Vp and because the via plug region VA is disposed between the first and second cell regions CAa and CAb. In addition, the word line control circuit may be simplified, the occupied area of the circuit may be reduced, and the two-dimensional size of the three-dimensional semiconductor device may be reduced because one word line control circuit can simultaneously or exclusively turn on/off the memory cells in the two cell regions CAa and CAb. That is, productivity can be increased, and unit cost can be reduced because more three-dimensional semiconductor chips can be integrated on one wafer.

The lower insulating layer 21, the interlayer insulating layers 23, and the upper insulating layer 24 may include an insulating material such as silicon oxide to insulate the stacked word lines 31.

Each of the via plugs Vp may be connected to one of the word lines 31 by vertically penetrating the word line stack 30. Side surfaces of the via plugs Vp and side surfaces of the word lines 31 may be insulated. The via plugs Vp may include a conductive core having a pillar shape and an insulating liner having a cylindrical shape to surround a sidewall of the core. The conductive core may include a conductor such as a metal, and the liner may include an insulating material such as silicon oxide. In an embodiment, a barrier material such as titanium nitride may further be included between the conductive core and the liner.

Lower ends of the via plugs Vp may be exclusively and electrically connected to the word lines 31, respectively. Accordingly, the via plugs Vp may have different vertical lengths. In order to facilitate understanding of this embodiment, the vertical lengths of the via plugs Vp are described as gradually increasing, as an example. Accordingly, each of the via plugs Vp may exclusively provide a voltage or a current to a corresponding word line 31.

The lower layer 10 may include a logic device layer. For example, the lower layer 10 may include transistors disposed on the lower substrate, vertical conductive wirings, lateral conductive wirings, and a conductive common source electrode layer. The lower substrate may include a silicon layer, the transistors may include MOS transistors, and the vertical and lateral conductive wirings may include metal wirings. The conductive common source electrode layer may be provided in a plate form under the lower insulating layer 21 of the word line stack 30. The conductive common source electrode layer may include a doped polycrystalline silicon layer or a metal silicide layer. The lower layer 10 may include an insulating material such as silicon oxide or silicon nitride.

The three-dimensional semiconductor device may further include a capping insulating layer 25, contact plugs 35, and metal wirings 36. The capping insulating layer 25 may cover the word line stack 30 and the via plugs Vp. The capping insulating layer 25 may include an insulating material such as silicon oxide. The contact plugs may be connected to the via plugs Vp, respectively, by penetrating through the capping insulating layer 25. The metal wirings 36 may be disposed on the capping insulating layer 25 and may be connected to the contact plugs 35, respectively. The contact plugs 35 and metal wirings may include a metal such as tungsten (W), a barrier metal such as titanium nitride (TiN), or other conductive materials.

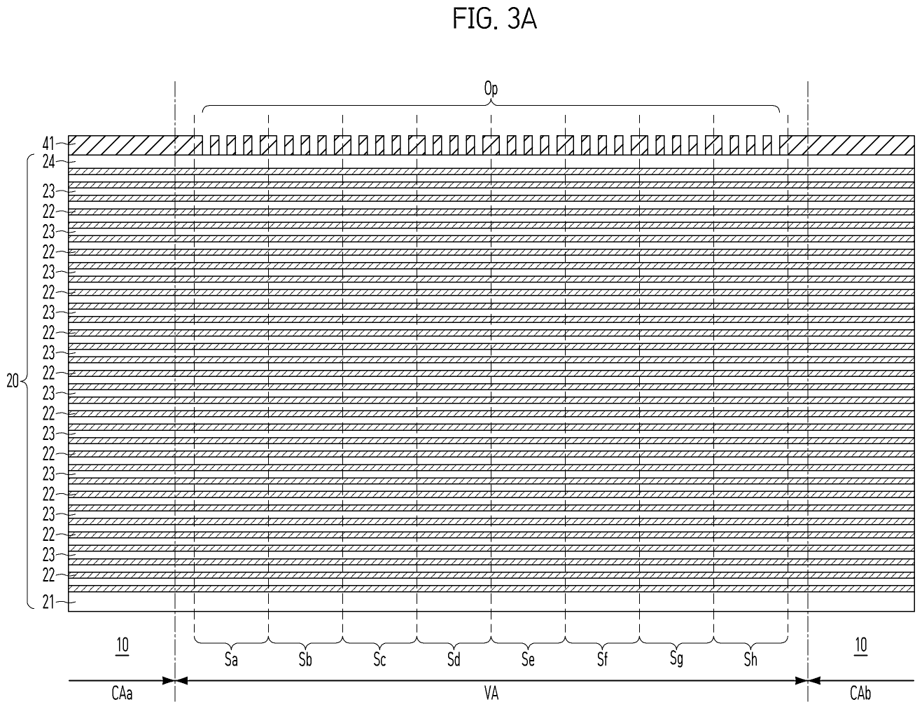

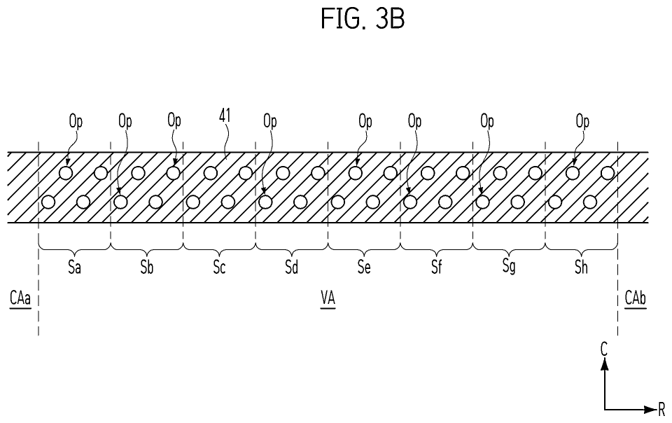

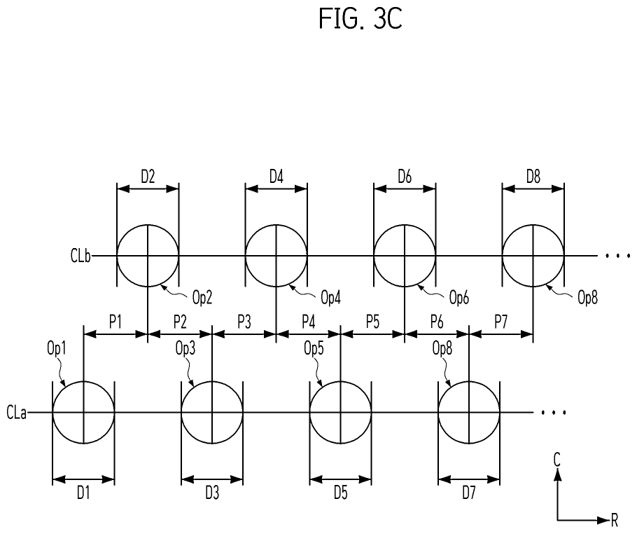

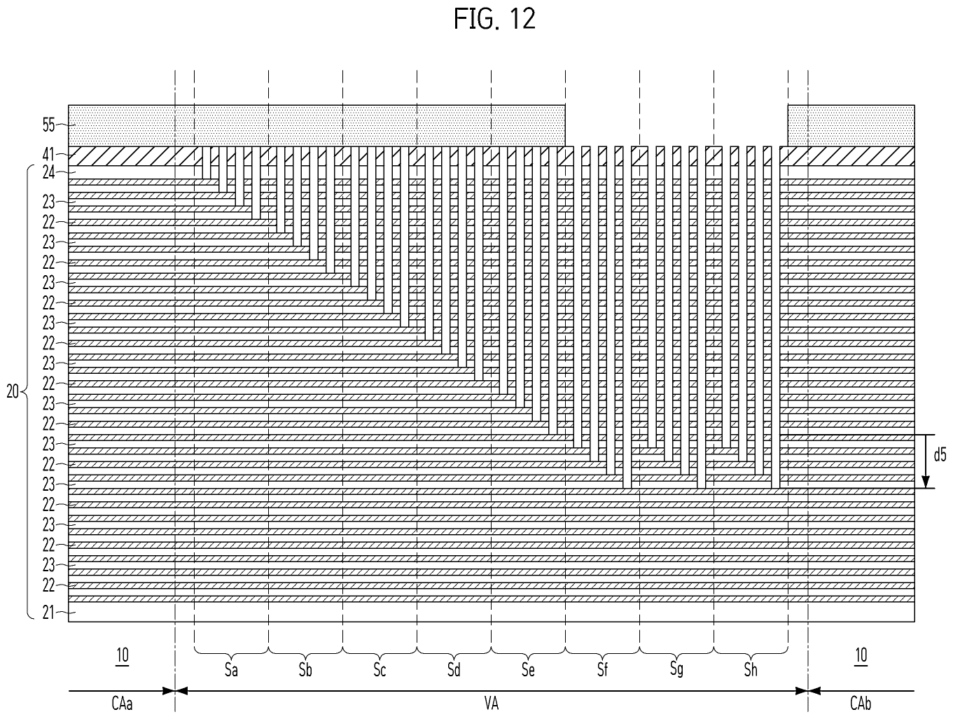

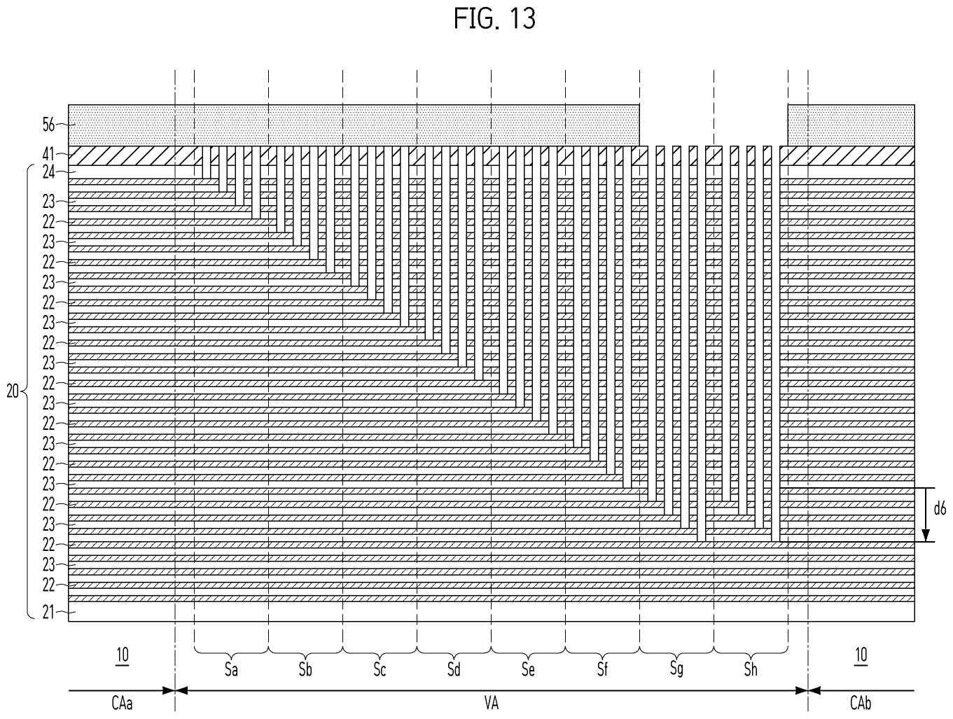

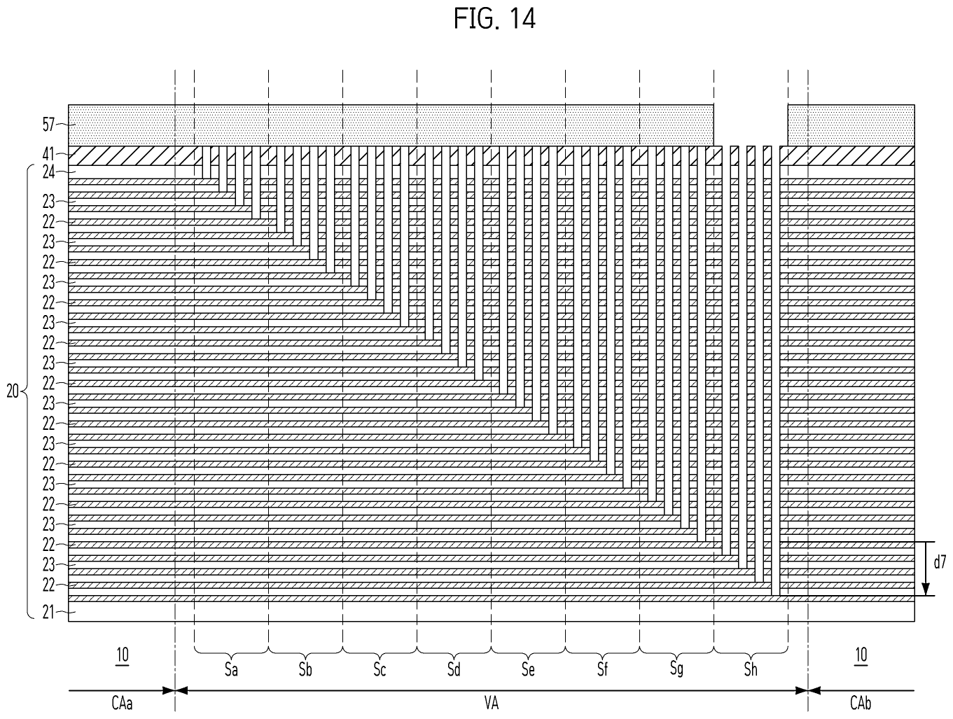

FIGS. 3A to 18 are diagrams illustrating a method of fabricating a three-dimensional semiconductor device according to an embodiment of the present disclosure. In these figures, the longitudinal cross-sectional views taken along lines I-I′ and II-II′ in FIG. 1C are overlapped, but adjacent patterns in the drawings may be spaced apart in a diagonal direction in a plan or top view.

Referring to FIG. 3A, a method for fabricating a three-dimensional semiconductor device according to an embodiment of the present disclosure may include forming an insulating layer stack 20 on the lower layer 10 and a hard mask pattern 41 on the insulating layer stack 20. The insulating layer stack 20 may include a lower insulating layer 21, a plurality of sacrificial insulating layers 22 and a plurality of interlayer insulating layers 23, which are alternately stacked, and an upper insulating layer 24. The lower insulating layer 21, the interlayer insulating layers 23, and the upper insulating layer 24 may include an insulating material such as silicon oxide. The sacrificial insulating layers 22 may include an insulating material such as silicon nitride, which may have an etching selectivity with respect to the lower insulating layer 21, the interlayer insulating layers 23, and the upper insulating layer 24. The hard mask pattern 41 may have a plurality of openings Op. The insulating layer stack 20 may be divided into a first cell region CAa, a second cell region CAb, and a via plug region VA. The via plug region VA may be divided into a plurality of sites Sa to Sh.

FIG. 3B is a top view illustrating an arrangement of the openings Op of the hard mask pattern 41 of FIG. 3A. Referring to FIG. 3B, the openings Op may be arranged in a zigzag pattern, such that openings Op may be offset relative to each other in a row direction R and a column direction C. The openings Op may be arranged to be spaced apart in the row direction R so as not to overlap in the column direction C because each of the openings Op in the sites Sa to Sh must be exposed, one by one, by trimming process. The same number of openings Op may be disposed in each of the sites Sa to Sh. Although four openings Op are described to be formed in each of the sites Sa to Sh, in embodiments more than four openings Op may be formed in each of the sites Sa to Sh. For example, several to tens of the openings Op may be formed in each of the sites Sa to Sh.

FIG. 3C is a layout illustrating an example of one site with diameters D1 to D8 of the plurality of openings Op of the hard mask pattern 41 disposed according to pitches P1 to P7. Referring to FIG. 3C, the diameters D1 to D8 of the respective first to eighth openings Op1 to Op8 may be the same. In addition, the pitches P1 to P7 of the respective first to eighth openings Op1 to Op8 may be the same. The pitches P1 to P7 may be larger than the diameters D1 to D8. Accordingly, in the column direction C, the openings Op may not overlap. In another embodiment, the pitches P1 to P7 may increase in magnitude along the row direction R.

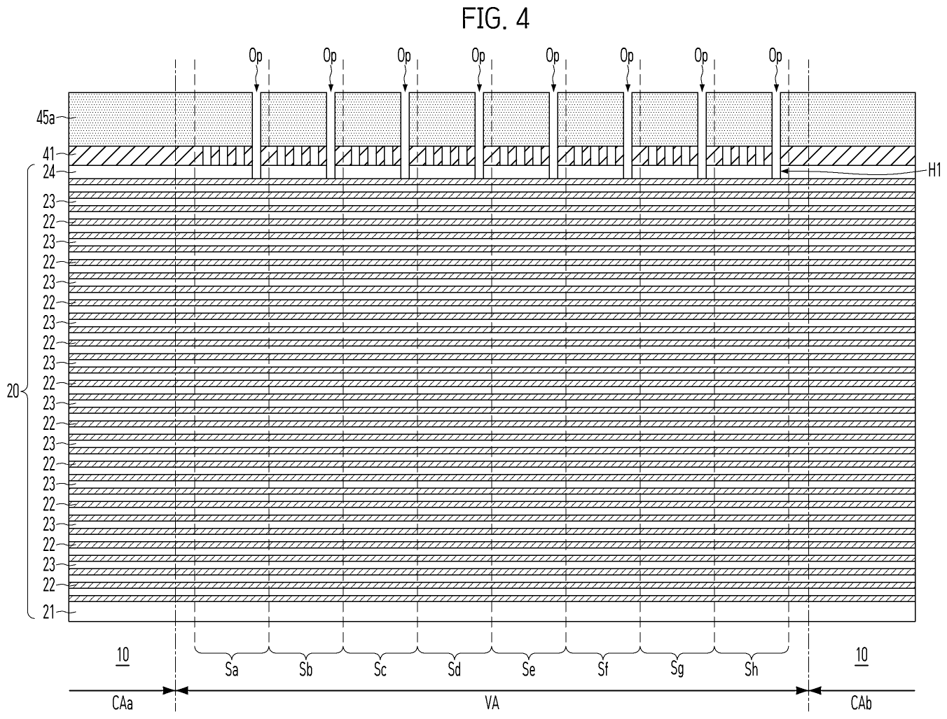

Referring to FIG. 4, the method may further include forming first hole patterns H1 in the insulating layer stack 20 by performing a first hole forming process. For example, the first hole forming process may include forming a first photoresist pattern 45a and forming the first hole patterns H1 by performing a first etching process, which uses the first photoresist pattern 45a and the hard mask pattern 41 as etching mask. The first photoresist pattern 45a may expose one of the outermost openings Op of the hard mask pattern 41 in each of the sites Sa to Sh. For example, the opening Op in each of the sites Sa to Sh that is furthest in the row direction may be exposed. The first hole patterns H1 may extend under the hard mask pattern 41 downward to the inside of the insulating layer stack 20.

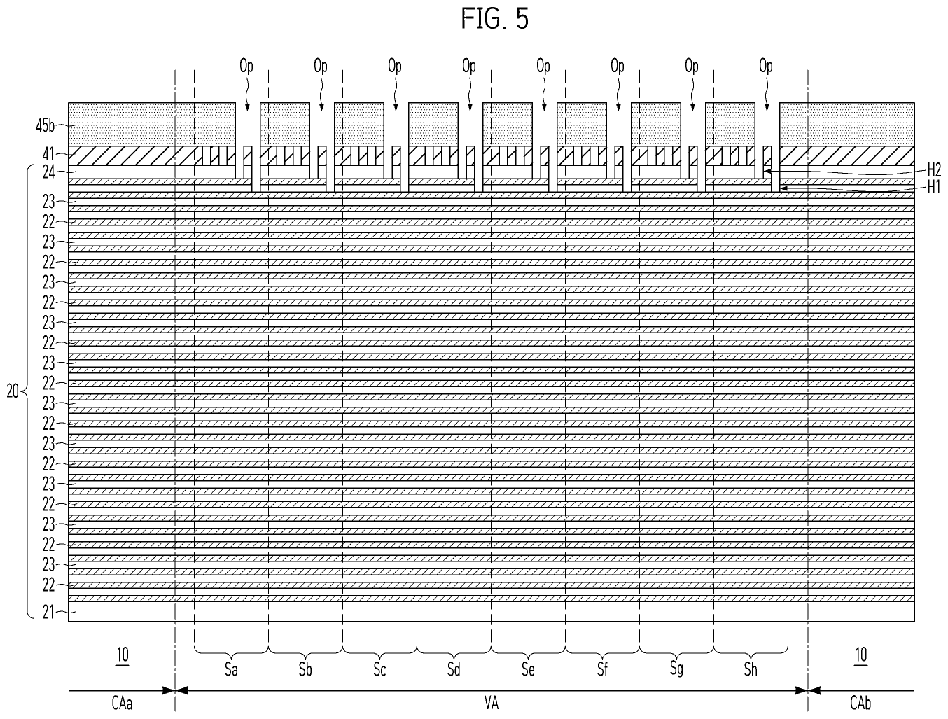

Referring to FIG. 5, the method may further include forming second hole patterns H2 in the insulating layer stack 20 by performing a second hole forming process, and further deepening the first hole patterns H1. The second hole forming process may include forming a second photoresist pattern 45b, which exposes the openings OP that are adjacent to the openings Op of the hard mask pattern 41 previously exposed in the first hole forming process. The second photoresist pattern 45b may be formed by shrinking the first photoresist pattern 45a, and the second hole patterns H2 and the deepened first hole patterns H1 can be formed by the second etching process using the second photoresist pattern 45b and the hard mask pattern 41 as etching masks.

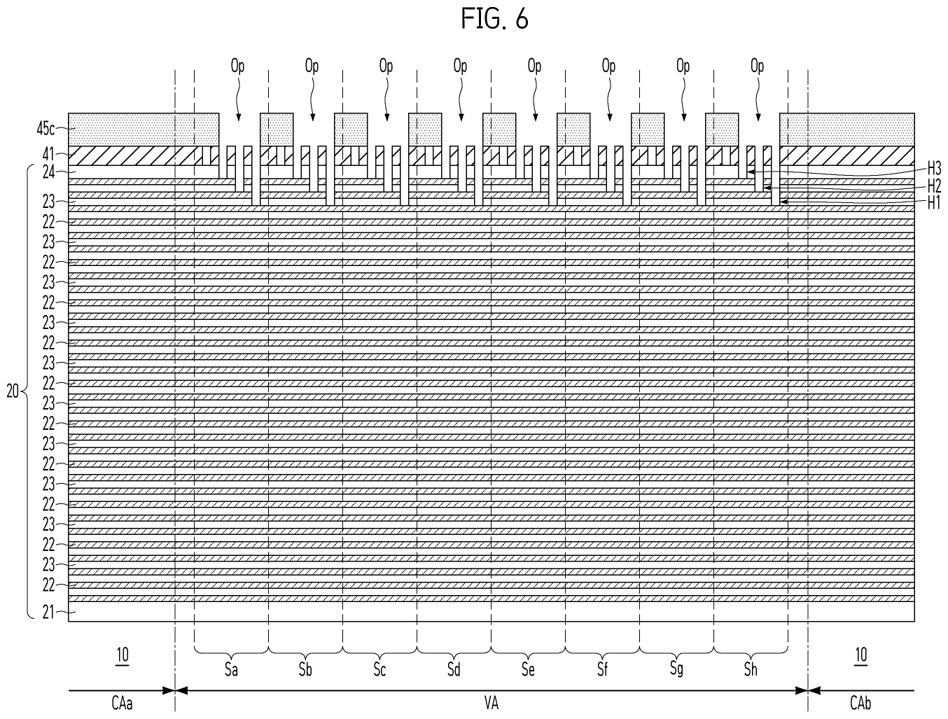

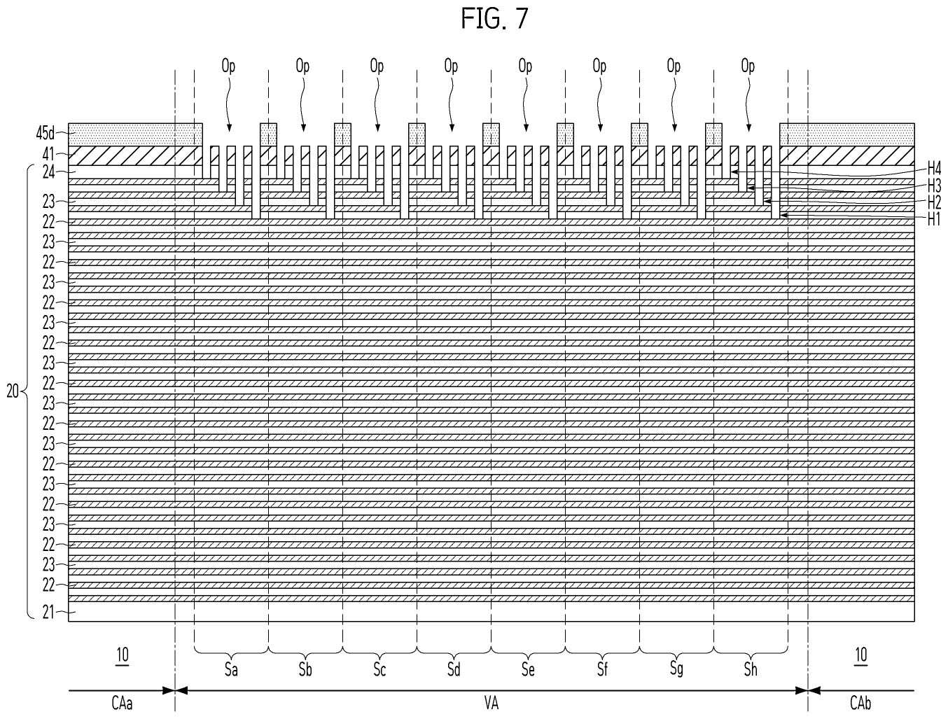

Referring to FIGS. 6 and 7, the method may further include forming third hole patterns H3 and fourth hole patterns H4 in the insulating layer stack 20 by performing a third hole forming process and a fourth hole forming process. The first hole patterns H1 and the second hole patterns H2 may further be deepened with each additional hole forming process. In the third hole forming process, the second photoresist pattern 45b may shrink to a third photoresist pattern 45c to expose additional openings Op of the hard mask pattern 41. In the fourth hole forming process, the third photoresist pattern 45c may shrink to a fourth photoresist pattern 45d, which exposes additional openings Op of the hard mask pattern 41.

In FIGS. 4 to 7, the openings Op of the hard mask pattern 41 in each of the sites Sa to Sh may be sequentially exposed in the row direction. Similar to FIG. 3C, the openings Op of the hard mask pattern 41 in each of the sites Sa to Sh may be disposed to be spaced apart in the row direction R.

As described above, four hole patterns H1 to H4 are described to be formed in each of the sites Sa to Sh, but more hole patterns may be formed in each of the sites Sa to Sh in methods disclosed herein. For example, several to tens of the hole patterns H1 to H4 may be formed in each of the sites Sa to Sh. Accordingly, the hole forming processes may be repeated until all the openings Op of the hard mask pattern 41 in each of the sites Sa to Sh are exposed.

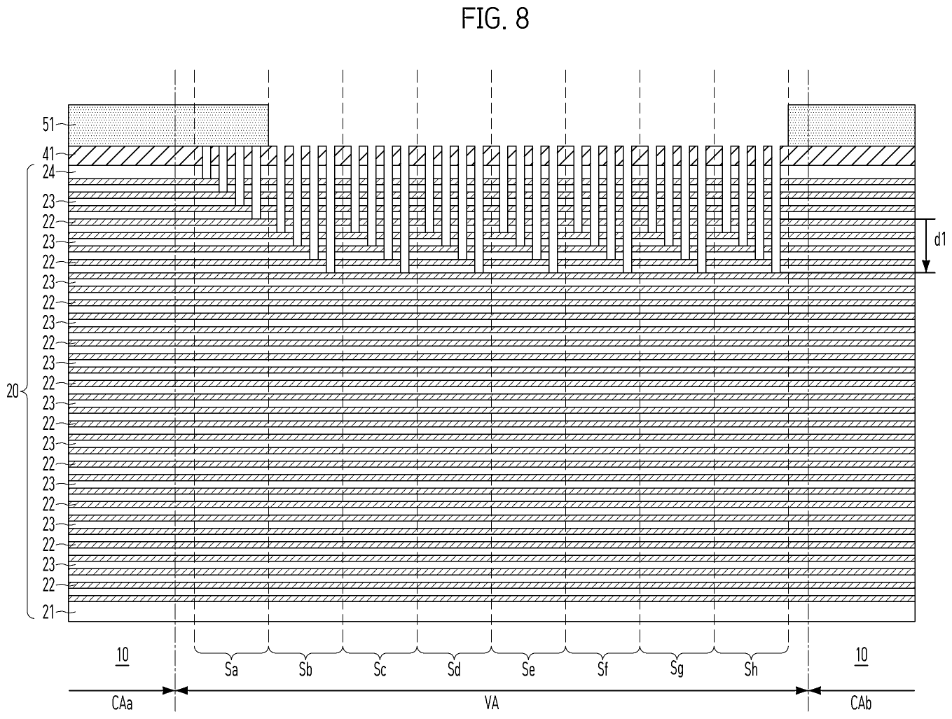

Referring to FIG. 8, the method may further include performing a first slimming process. The first slimming process may include forming a first mask pattern 51 covering one of the sites Sa to Sh (e.g., the first site Sa), exposing the remaining sites Sb to Sh, and further etching the hole patterns H1 to H4 of the exposed sites Sb to Sh by a first depth d1. Thereafter, the first mask pattern 51 may be removed, and a filling insulating material may fill in the hole patterns H1 to H4. Reference numerals for the filling insulation materials have been omitted to simplify the drawings.

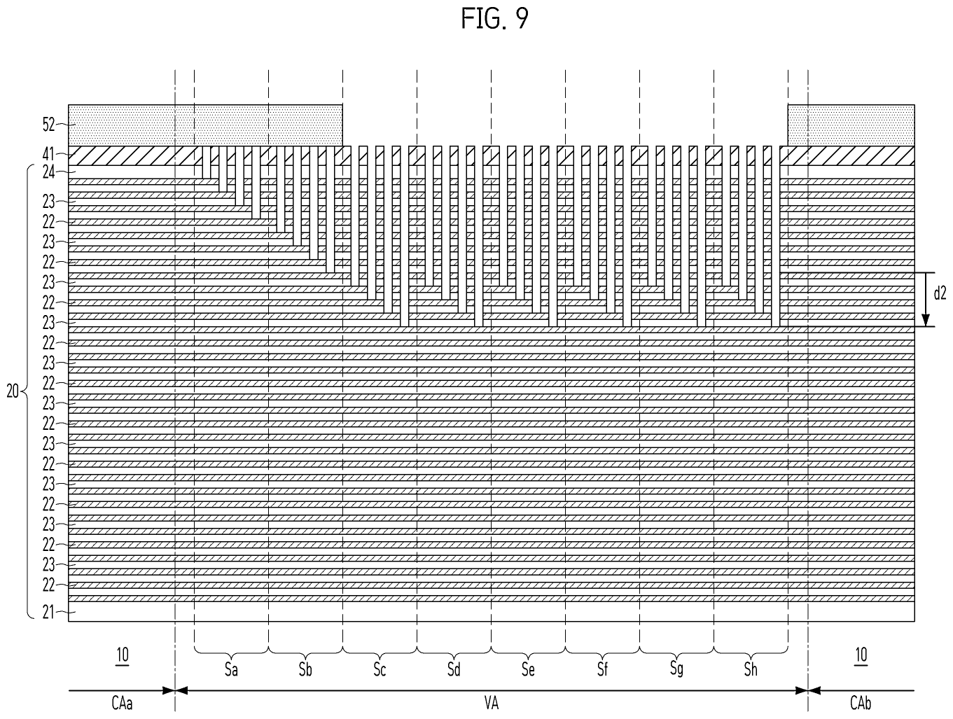

Referring to FIG. 9, the method may further include a second slimming process. The second slimming process may include forming a second mask pattern 52 covering at least two of the sites Sa to Sh (e.g., the first and second sites Sa and Sb), exposing the remaining sites Sc to Sh, and further etching the hole patterns H1 to H4 of the exposed sites Sc to Sh by a second depth d2. In the drawing, the first and second sites Sa and Sb are shown to be adjacent to each other, but in other embodiments, the first and second sites Sa and Sb may be spaced apart from each other. Reference numerals of the hole patterns H1 to H4 have been omitted in order to avoid complicating the drawing. Thereafter, the second mask pattern 52 may be removed and a filling insulating material may be used to fill in the hole patterns.

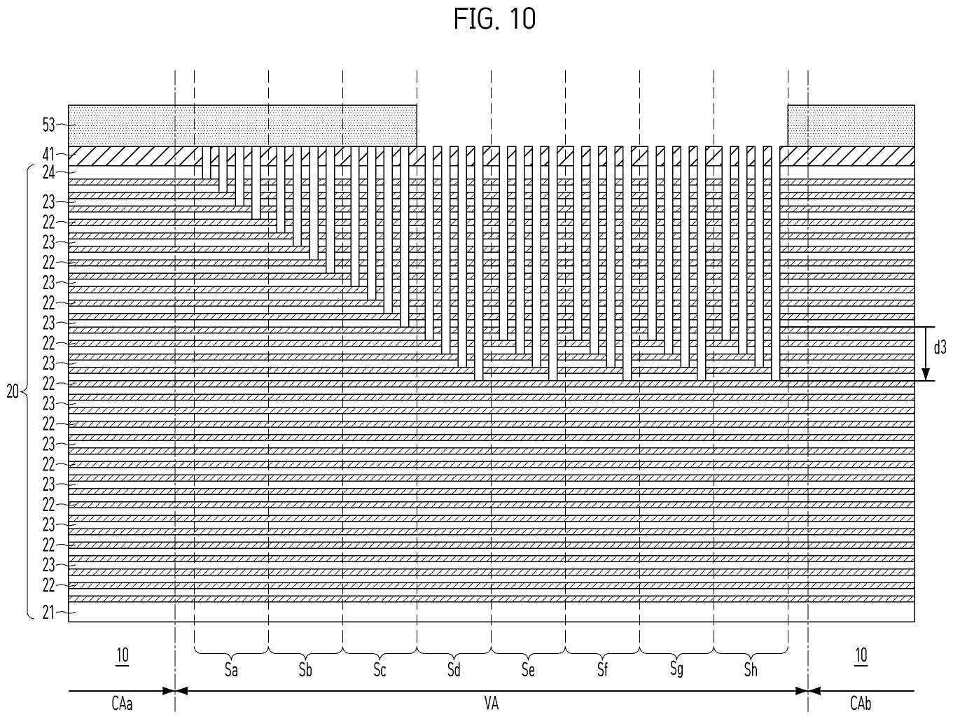

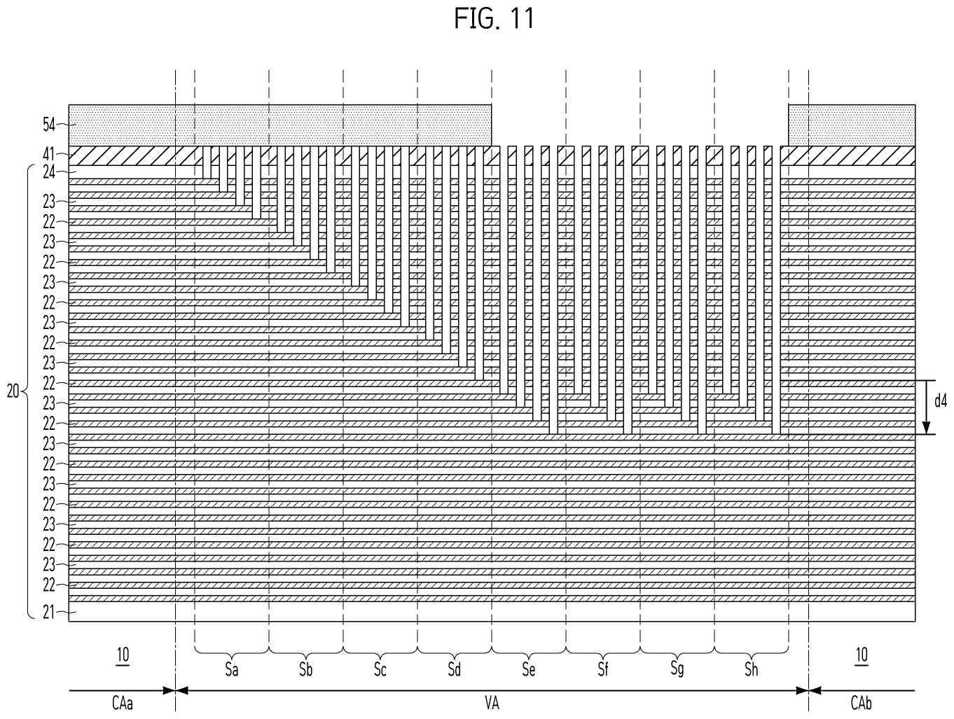

Referring to FIGS. 10 to 14, the method may further include performing third to seventh slimming processes. The third to seventh slimming processes may include forming third to seventh mask patterns 53 to 57, respectively, that cover and expose some of the sites Sa to Sh, and further etching the hole patterns H1 to H4 the exposed sites Sd to Sh of by one of third to seventh depths d3 to d7. Although sites Sa to Sh are described as adjacent to each other and sequentially exposed in the drawings, adjacent sites do not have to be sequentially exposed. Each of the third to seventh slimming processes may include removing the third to seventh mask patterns 53 to 57 respectively and filling in the hole patterns with a filling insulating material.

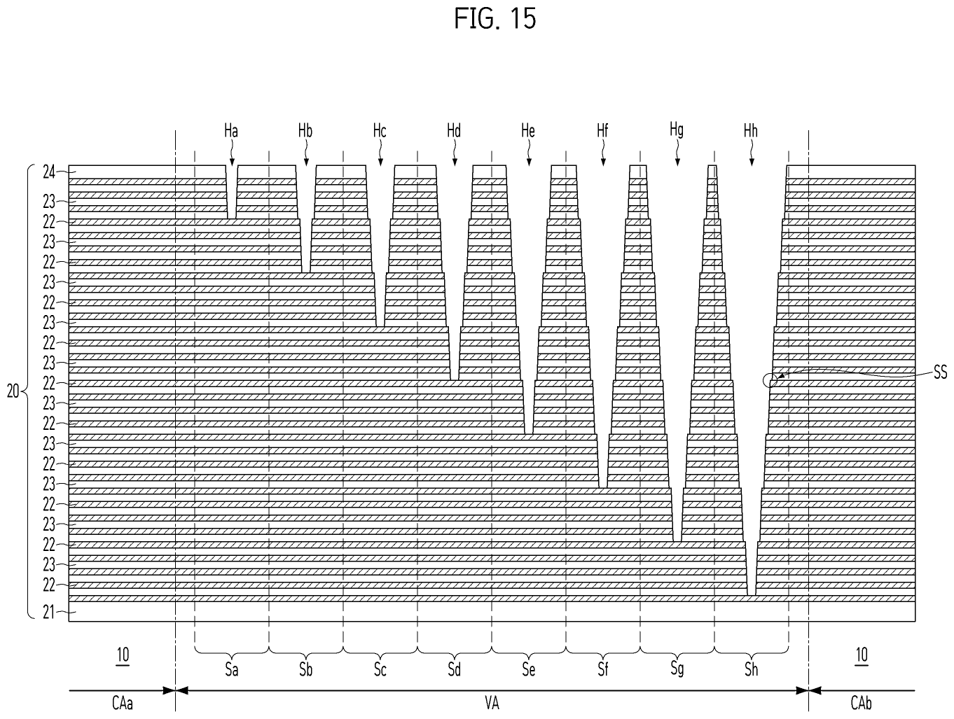

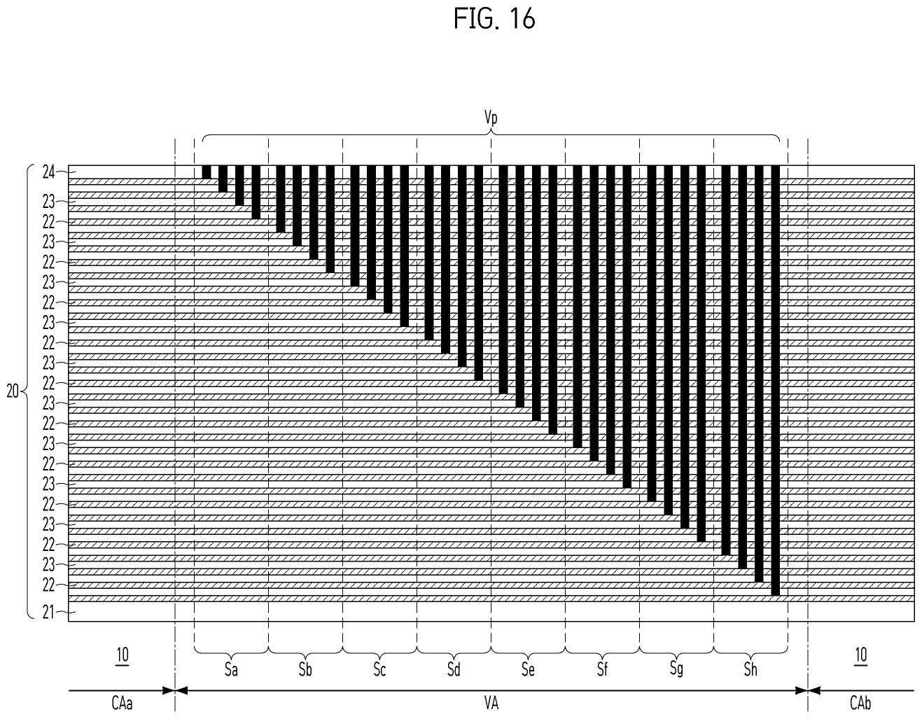

FIG. 15 is a diagram illustrating inner wall profiles of representative hole patterns Ha to Hh formed in each of the sites Sa to Sh. The inner wall profiles have been exaggerated to facilitate understanding of the technical features of the present disclosure. Referring to FIG. 15, the inner walls of the hole patterns Ha to Hh may be tapered. With further reference to FIGS. 8 to 14, the inner walls of the hole patterns Ha to Hh may have a step shape or a sill shape SS depending on the number of times the above-described slimming processes are performed. The sill shapes SS of the hole patterns Ha to Hh may be formed at the same levels because it is assumed that the slimming processes etch the hole patterns Ha to Hh by the same depths d1 to d7. In other embodiments, however, the depths d1 to d7 of the slimming processes may be different from each other. Accordingly, the sill shapes SS of the hole patterns Ha to Hh may be formed at different levels.

Referring to FIG. 16, the method may further include forming conductive via plugs Vp in the hole patterns Ha to Hh by performing a via plug forming process.

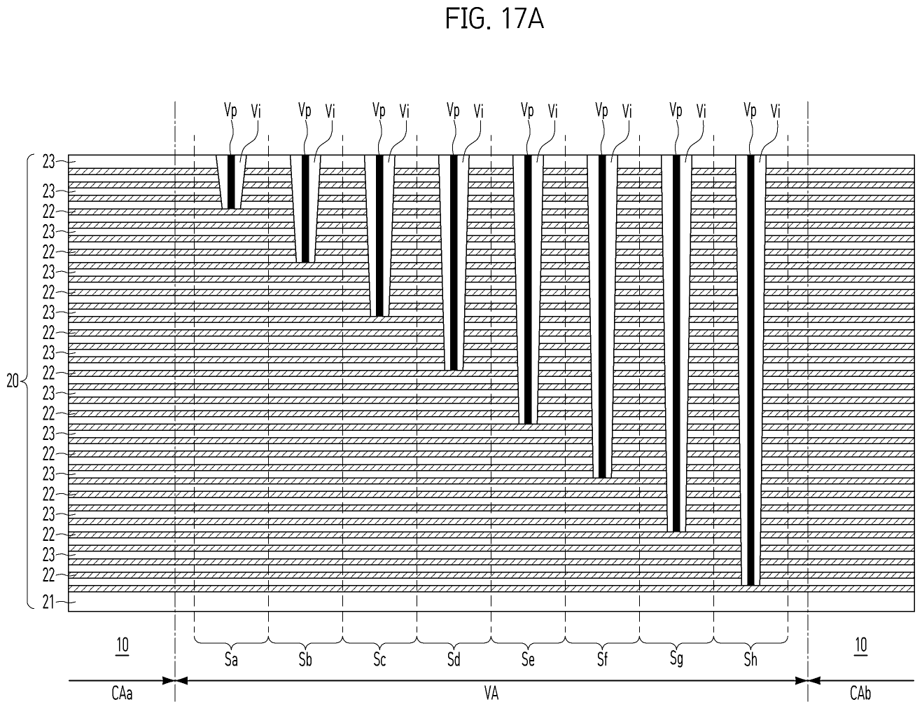

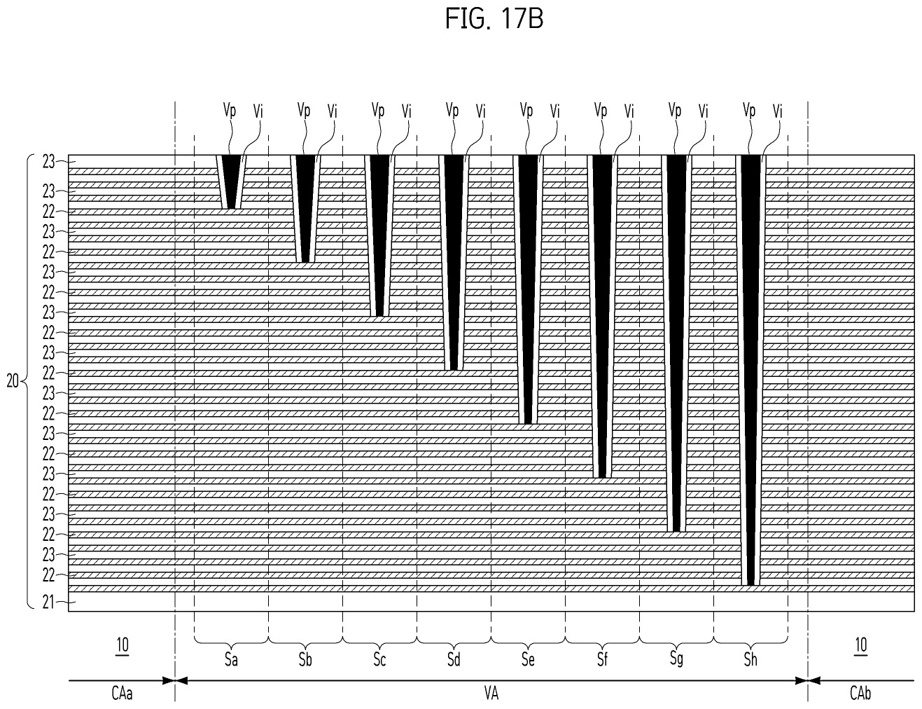

FIGS. 17A and 17B are longitudinal cross-sectional views conceptually illustrating a via plug forming process according to embodiments of the present disclosure. The sill shapes SS of FIG. 15 are omitted.

Referring to FIGS. 17A and 17B, the via plug forming process may include filling via insulators Vi in the hole patterns Ha to Hh, forming holes exposing each of the sacrificial insulating layers 22 by vertically penetrating the via insulator Vi, filling conductive materials in the holes in the via insulators Vi, and forming the via plugs Vp contacting the sacrificial insulating layers 22, respectively, by performing a planarization process.

Referring to FIG. 17A, the via plugs Vp may have a vertical sidewall profile. For example, the via plugs Vp may have a pillar shape. The via insulators Vi may have a filler shape.

Referring to FIG. 17B, the via plugs Vp may have an inclined sidewall profile. For example, the via plugs Vp may have an inverted cone shape or a stud shape. The via insulators Vi may have a lining shape.

The via insulator Vi may include silicon oxide or metal oxide. The via plugs Vp may include a metal. In FIGS. 17A and 17B, the diameters of the via plugs Vp may be the same. The via plugs Vp are illustrated in an exaggerated form to facilitate understanding of the technical features of the present disclosure.

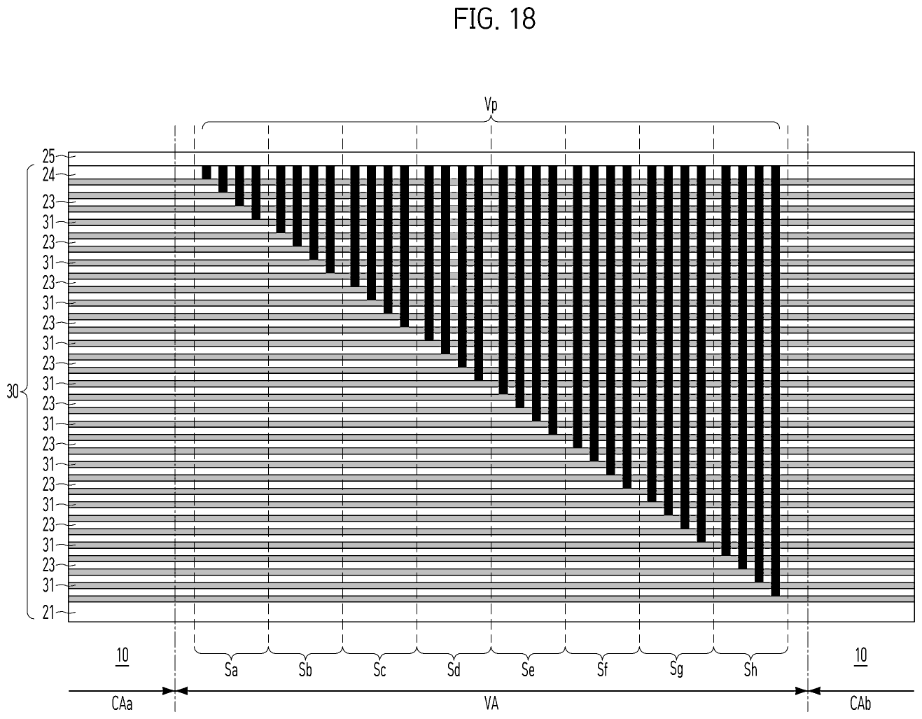

Referring to FIG. 18, the method may further include forming the capping insulating layer 25 over the insulating layer stack and forming the word line stack 30 by replacing the sacrificial insulating layers 22 with the word lines 31. The word line stack 30 may include the lower insulating layer 21, the interlayer insulating layers 23 and the word lines 31, which are alternately stacked, and the upper insulating layer 24. The capping insulating layer 25 may include silicon oxide having an etching selectivity with respect to the sacrificial insulating layers 22. The word lines 31 may include a conductor such as a metal.

Thereafter, referring to FIG. 2, the method may further include forming contact plugs 35 vertically penetrating the capping insulating layer 25 and forming metal wirings 36 over the capping insulating layer 25 and the contact plugs 35.

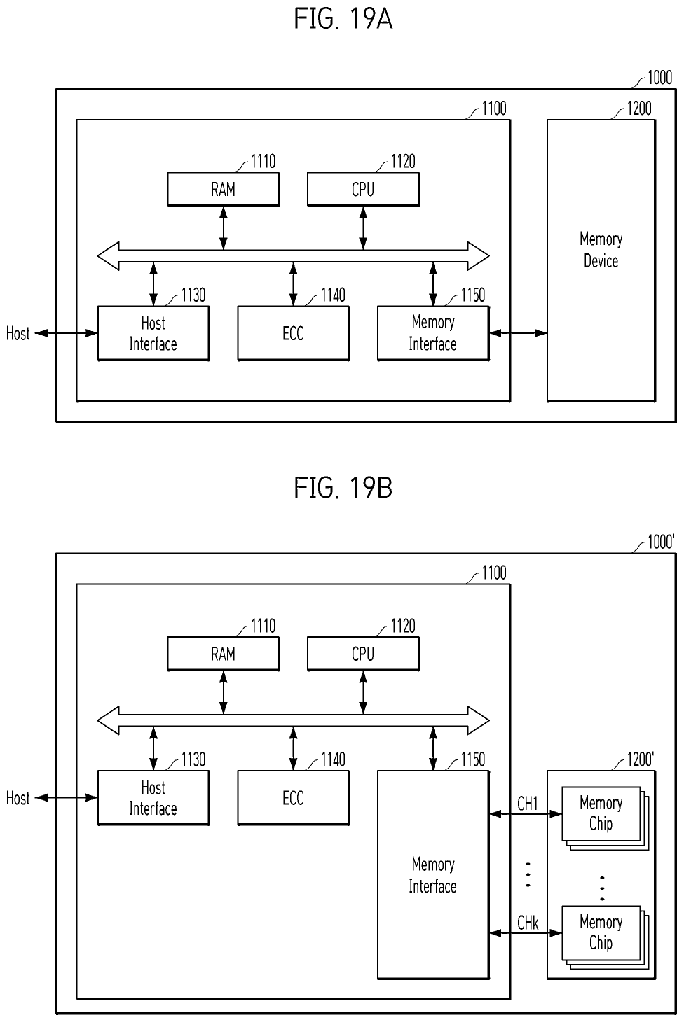

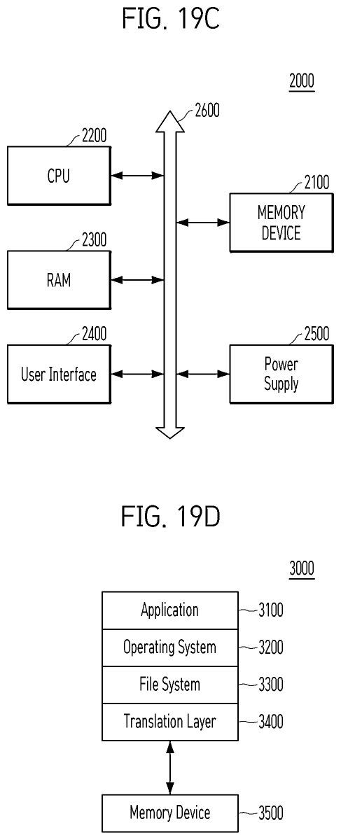

FIG. 19A is a block diagram illustrating a configuration of a memory system 1000 according to an embodiment of the present disclosure. Referring to FIG. 19A, a memory system 1000 according to an embodiment of the present disclosure may include a memory device 1200 and a controller 1100. The memory device 1200 may store data information having various data types such as text, graphics, and software codes. The memory device 1200 may include a nonvolatile memory. Also, the memory device 1200 may include the three-dimensional semiconductor device described with reference to FIGS. 1A to 2. The controller 1100 may be connected to the host and the memory device 1200. The controller 1100 may access the memory device 1200 in response to a request from the host. For example, the controller 1100 may control operations of the memory device 1200 such as read, write, erase, and background. The controller 1100 may include, for example, a random-access memory (RAM) 1110, a central processing unit (CPU) 1120, a host interface 1130, an error correction code (ECC) circuit 1140, and a memory interface 1150. Here, the RAM 1110 may be used as an operating memory of the CPU 1120, a cache memory between the memory device 1200 and a host, a buffer memory between the memory device 1200 and a host, and the like. For reference, the RAM 1110 may be replaced with static random-access memory (SRAM), read only memory (ROM), or the like. The CPU 1120 may control the overall operation of the controller 1100. For example, the CPU 1120 may operate a firmware such as a flash translation layer (FTL) stored in the RAM 1110. The host interface 1130 may interface with a host. For example, the controller 1100 may communicate with a host through various interface protocols including at least one of USB (Universal Serial Bus) protocol, MMC (Multi-Media Card) protocol, PCI (Peripheral Component Interconnection) protocol, PCI-E (PCI-Express) protocol, ATA (Advanced Technology Attachment) protocol, Serial-ATA protocol, Parallel-ATA protocol, SCSI (Small Computer Small Interface) protocol, ESDI (Enhanced Small Disk Interface) protocol, and IDE (Integrated Drive Electronics) protocol, private protocol, and etc. The ECC circuit 1140 may detect and correct an error included in data read from the memory device 1200 using an error correction code ECC. The memory interface 1150 may interface with the memory device 1200. For example, the memory interface 1150 may include a NAND interface or a NOR interface. The buffer memory may temporarily store data transmitted to the outside through the host interface 1130 or may temporarily store data transmitted from the memory device 1200 through the memory interface 1150. In addition, the controller 1100 may further include a ROM that stores code data for interfacing with a host. As described above, the performance of the memory system 1000 may be improved because the memory system 1000 according to an embodiment of the present disclosure includes the memory device 1200 with improved performance.

FIG. 19B is a block diagram illustrating a configuration of a memory system 1000′ according to an embodiment of the present disclosure. Hereinafter, duplicate descriptions will be omitted below. Referring to FIG. 19B, the memory system 1000′ according to an embodiment of the present disclosure may include a memory device 1200′ and the controller 1100. In addition, the controller 1100 may include a RAM 1110, CPU 1120, host interface 1130, ECC circuit 1140, memory interface 1150, and the like. The memory device 1200′ may include a nonvolatile memory. Also, the memory device 1200′ may include the three-dimensional semiconductor device described with reference to FIGS. 1A to 2. Also, the memory device 1200′ may include a multi-chip package including a plurality of memory chips. The plurality of memory chips may be divided into a plurality of groups, and the plurality of groups may communicate with the controller 1100 through first to k-th channels CH1 to CHk. Also, memory chips belonging to one group may communicate with the controller 1100 through a common channel. For reference, the memory system 1000′ may be modified so that one memory chip is connected to one channel. As described above, the performance of the memory system 1000′ may also be improved because the memory system 1000′ according to an embodiment of the present disclosure includes the memory device 1200′ with improved performance. In particular, the memory device 1200′ may have the increased data storage capacity and the improved operation speed because the memory device 1200′ includes a multi-chip package.

FIG. 19C is a block diagram illustrating a configuration of a computing system 2000 according to an embodiment of the present disclosure. Hereinafter, duplicate descriptions will be omitted below. Referring to FIG. 19C, a computing system 2000 according to an embodiment of the present disclosure may include a memory device 2100, CPU 2200, RAM 2300, user interface 2400, power supply 2500, and system bus 2600, and the like. The memory device 2100 may store data provided through the user interface 2400 and data processed by the CPU 2200. In addition, the memory device 2100 may be electrically connected to the CPU 2200, the RAM 2300, the user interface 2400, the power supply 2500, and the like through the system bus 2600. For example, the memory device 2100 may be connected to the system bus 2600 through a controller (not shown) or may be directly connected to the system bus 2600. When the memory device 2100 is directly connected to the system bus 2600, the function of the controller may be performed by the CPU 2200, the RAM 2300, or the like. Here, the memory device 2100 may include a nonvolatile memory. Also, the memory device 2100 may include the three-dimensional semiconductor device described with reference to FIGS. 1A to 2. The computing system 2000 may include a computer, Ultra Mobile PC (UMPC), workstation, netbook, Personal Digital Assistants (PDA), portable computer, web tablet, wireless phone, mobile phone, smart phone, e-book, PMP (Portable Multimedia Player), portable game console, navigation device, black box, digital camera, three-dimensional television, digital audio recorder, digital audio player, digital picture recorder, digital picture player, digital video recorder, digital video player, one of the devices that can transmit and receive information in a wireless environment, one of the various electronic devices that make up a home network, one of the various electronic devices that make up a computer network, one of the various electronic devices that make up a telematics network, or a RFID device. The performance of the computing system 2000 may also be improved because the computing system 2000 according to an embodiment of the present disclosure includes the memory device 2100 with improved performance.

FIG. 19D is a block diagram illustrating a computing system 3000 according to an embodiment of the present disclosure. Referring to FIG. 19D, a computing system 3000 according to an embodiment of the present disclosure may include a software layer including an operating system 3200, an application 3100, a file system 3300, a translation layer 3400, and the like. In addition, the computing system 3000 may include a hardware layer such as a memory device 3500. The operating system 3200 may manage software and hardware resources of the computing system 3000 and may control the central processing unit to execute a program. The application 3100 may include various application programs executed by the computing system 3000. For example, the application 3100 may include a utility software executed by the operating system 3200. The file system 3300 refers to a logical structure for managing data, files, and the like existing in the computing system 3000. The file system 3300 may organize the files or data to be stored in the memory device 3500 according to rules. The file system 3300 may be determined depending on the operating system 3200 used for the computing system 3000. For example, when the operating system 3200 is a Windows series of Microsoft Corporation, the file system 3300 may include a File Allocation Table (FAT), an NT file system (NTFS), or the like. In addition, when the operating system 3200 is a Unix/Linux series, the file system 3300 may include an Extended File System (EXT), a Unix File System (UFS), a Journaling File System (IFS), or the like. Although the operating system 3200, the application 3100, and the file system 3300 are described in separate blocks, but the application 3100 and the file system 3300 may be included in the operating system 3200. The translation layer 3400 may translate an address into a format suitable for the memory device 3500 in response to a request from the file system 3300. For example, the translation layer 3400 may convert a logical address generated by the file system 3300 into a physical address of the memory device 3500. Here, mapping information between a logical address and a physical address may be stored in an address translation table. For example, the translation layer 3400 may include a Flash Translation Layer (FTL), a Universal Flash Storage Link Layer (ULL), and the like. The memory device 3500 may include a nonvolatile memory. Also, the memory device 3500 may include the three-dimensional semiconductor device described with reference to FIGS. 1A to 2. The performance of the computing system 3000 may be improved because the computing system 3000 according to an embodiment of the present disclosure includes the memory device 3500 with improved performance.

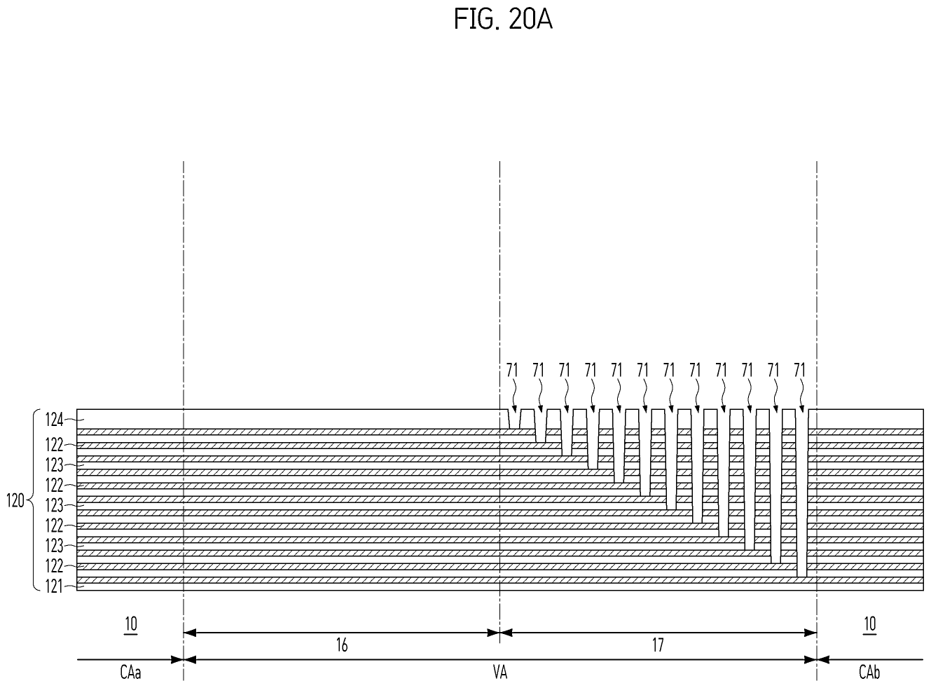

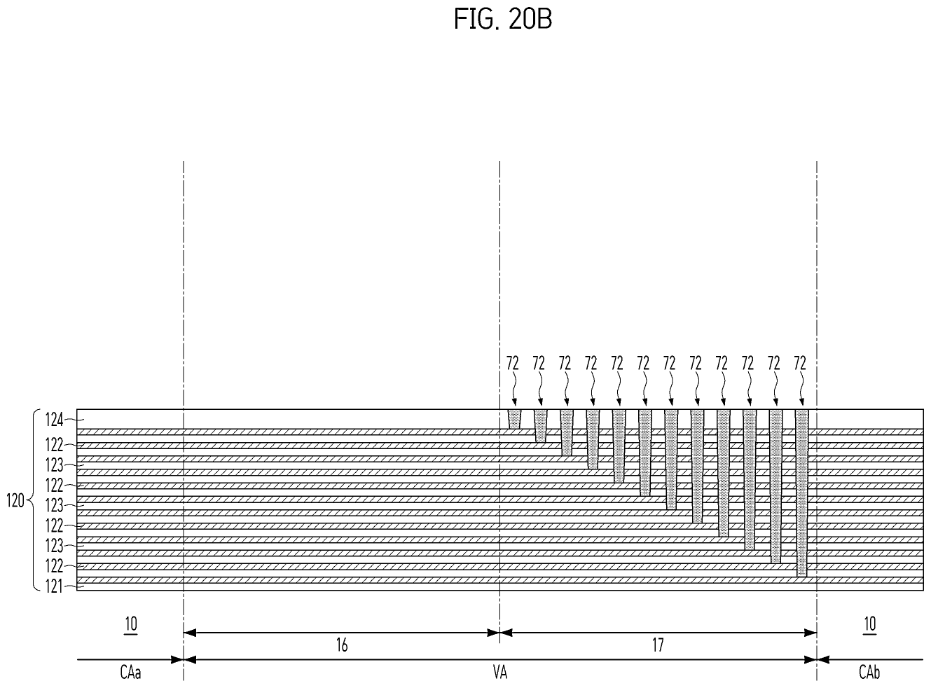

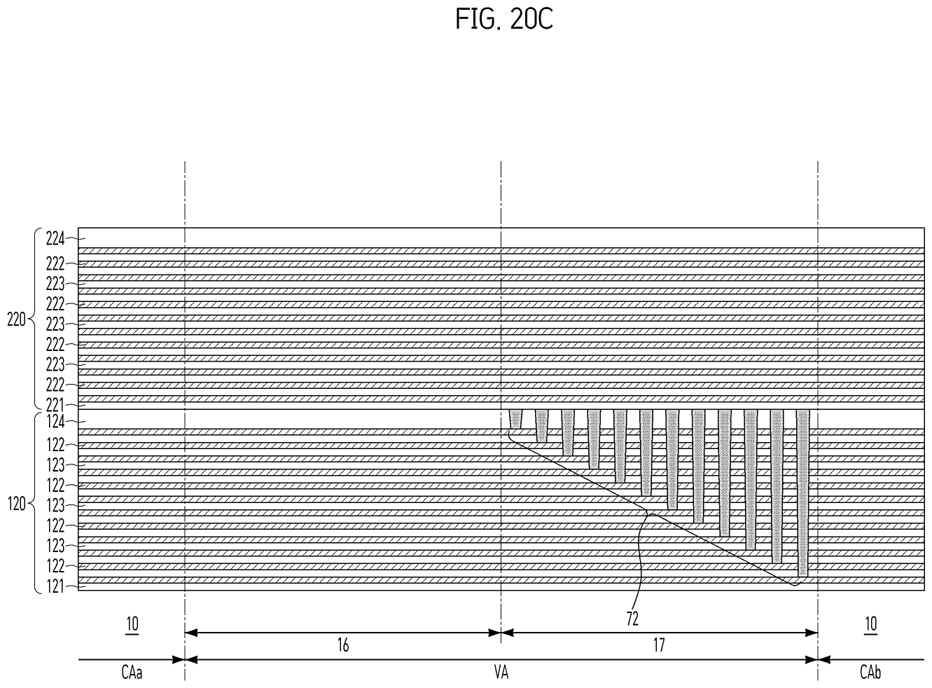

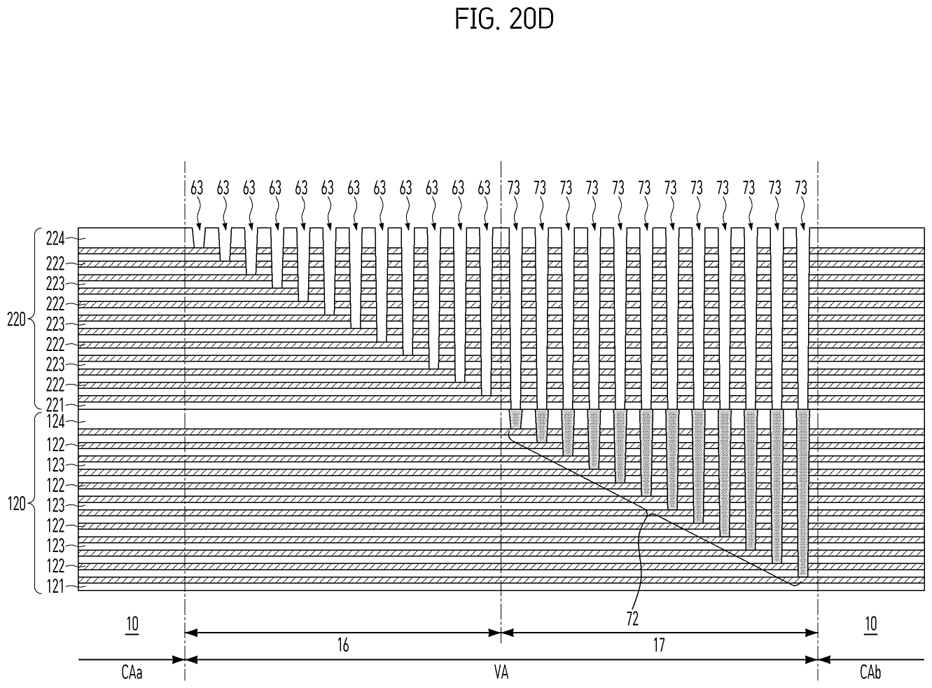

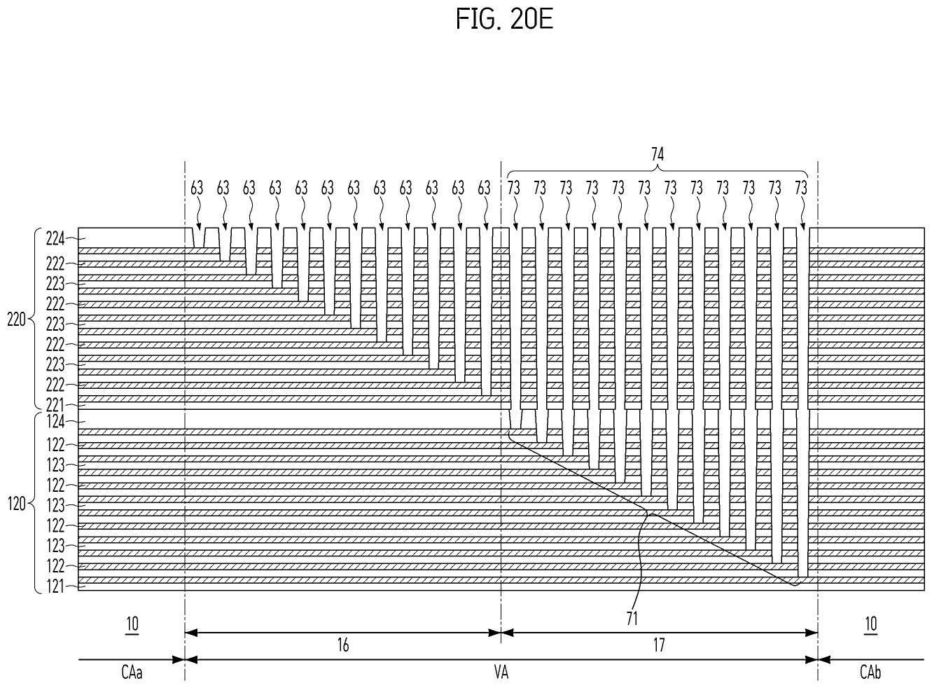

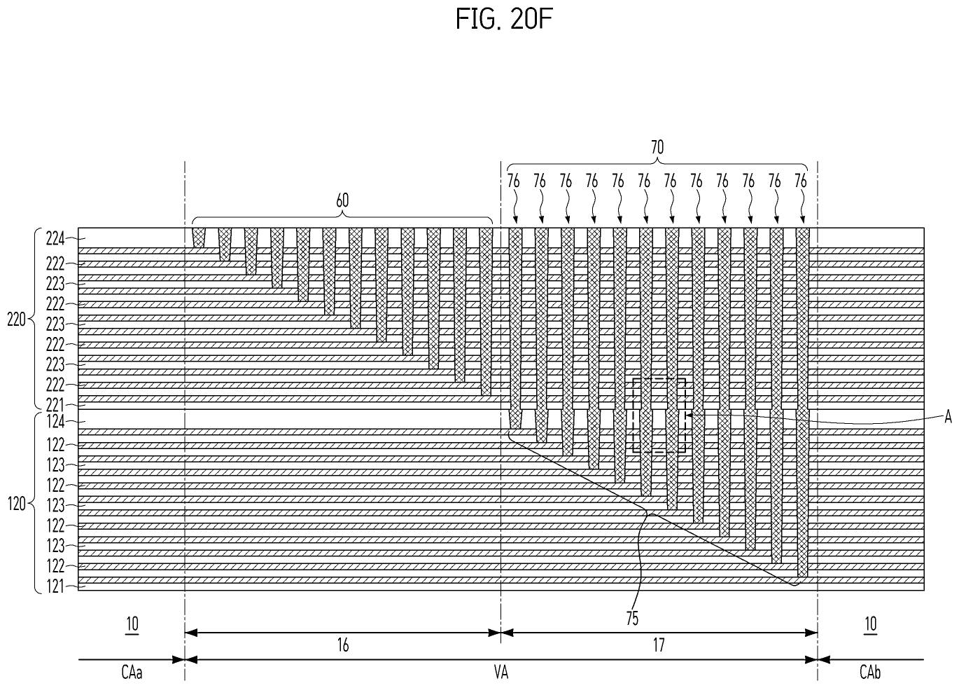

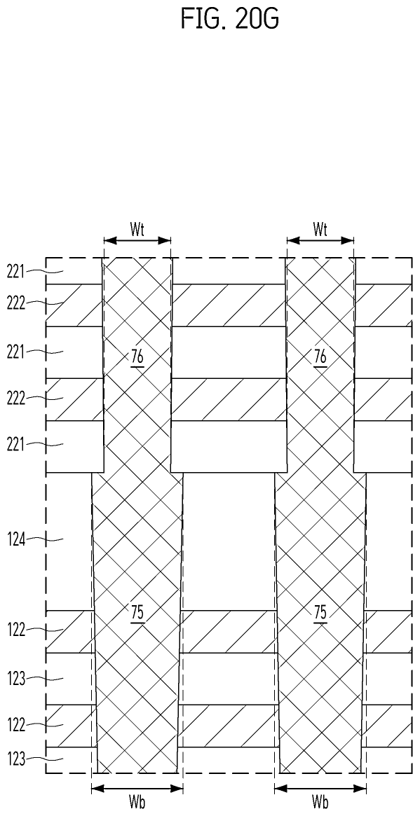

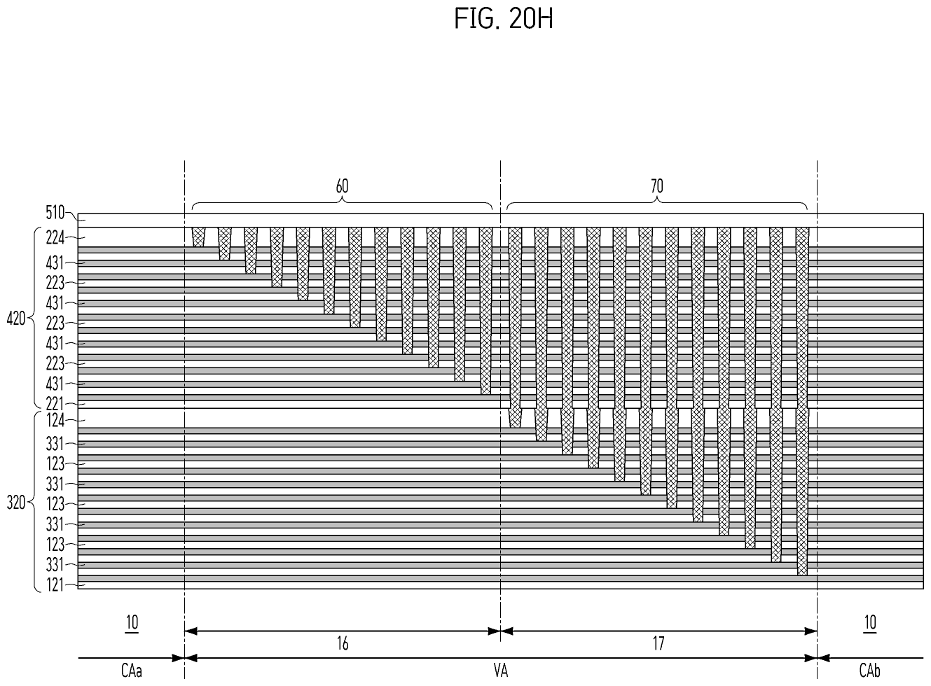

FIGS. 20A to 201 are diagrams illustrating a method of forming a three-dimensional semiconductor device according to an embodiment of the present invention. For example, longitudinal sectional views taken along the lines I-I′ and II-II′ of FIG. 1C are overlapped or in side-by-side, but adjacent patterns in the drawings may be spaced apart in a diagonal direction in a plan or top view.

Referring to FIG. 20A, the method may include forming a bottom insulating layer stack 120 over a lower layer 10, forming a bottom hard mask pattern (not shown), bottom photoresist patterns (not shown), and bottom mask patterns (not shown) over the bottom insulating layer stack 120, and performing etching processes to form bottom via hole patterns 71. The lower layer 10 and the bottom insulating layer stack 120 may include cell areas CAa and CAb and a via plug region VA between cell regions CAa and CAb.

Forming the bottom insulating layer stack 120 may include forming a bottom lower insulating layer 121, bottom sacrificial insulating layers 122, bottom interlayer insulating layers 123, and a bottom upper insulating layer 124 by performing deposition processes. Each of the bottom lower insulating layer 121, the bottom interlayer insulating layers 123, and the bottom upper insulating layer 124 may include a silicon oxide-based insulating layer. Each of the bottom sacrificial insulating layers 122 may include a silicon nitride-based insulating layer. The bottom sacrificial insulating layers 122 and the bottom interlayer insulating layers 123 may be alternately stacked between the bottom lower insulating layer 121 and the bottom upper insulating layer 124 in a vertical direction. The via plug region VA may include a top via plug region 16 and a bottom via plug region 17. The lower bottom via hole patterns 71 may not be formed in the top via plug region 16, and may be formed only in the bottom via plug region 17. The lower bottom via hole patterns 71 may gradually be deepened in one direction. The lower bottom via hole patterns 71 may have different depths with each other in the bottom plug region 17. The lower bottom via hole patterns 71 may extend to vertically pass through the bottom sacrificial insulating layers 122 and the bottom interlayer insulating layers 123 of the bottom insulating layer stack 120. Lower ends of the lower bottom via hole patterns 71 may abut the bottom sacrificial insulating layers 122, and expose surfaces to the corresponding bottom sacrificial insulating layers 122, respectively. That is, each hole patterns formed in the bottom via plug region 17—each the lower bottom via hole pattern 71 may be formed to correspond to each bottom sacrificial insulating layer 122 of the bottom insulating layer stack 120.

In an embodiment, the lower bottom via hole patterns 71 may correspond to the hole patterns H1 to H4 arranged in a zigzag pattern formed in one of the sites Sa-Sh, respectively. (See FIG. 7). In another embodiment, the lower bottom via hole patterns 71 may correspond to the representative hole patterns Ha-Hh in each of the sites Sa-Sh (see FIG. 15)

Referring to FIG. 20B, the method may further include forming sacrificial via plugs 72 by performing a filling process to fill the lower bottom via hole patterns 71 with a filling material. The sacrificial via plugs 72 may be formed only in the bottom via plug region 17. The sacrificial via plugs 72 may have different vertical lengths with each other in the bottom via plug region 17. The filling material may have an etch selectivity with silicon oxide and silicon nitride. For example, the filling material may include one of polysilicon, spin-on-dielectric (SOD), flowable oxide (FOX), or polymer organic materials. The method may further include performing a chemical mechanical polishing (CMP) process to planarize top surfaces of the sacrificial via plugs 72 and a top surface of the bottom upper insulating layer 124.

Referring to FIG. 20C, the method may further include forming a top insulating layer stack 220 over the bottom insulating layer stack 120. Forming the top insulating layer stack 220 may include forming a top lower insulating layer 221, top sacrificial insulating layers 222, top interlayer insulating layers 223, and a top upper insulating layer 224 by performing deposition processes. Each of the top lower insulating layer 221, the top interlayer insulating layers 223, and the top upper insulating layer 224 may include a silicon oxide-based insulating layer. Each of the top sacrificial insulating layers 222 may include a silicon nitride-based insulating layer. The top sacrificial insulating layers 222 and the top interlayer insulating layers 223 may be alternately stacked between the top lower insulating layer 221 and the top upper insulating layer 224 in the vertical direction.

Referring to FIG. 20D, the method may further include forming a top hard mask pattern (not shown), top photoresist patterns (not shown), and top mask patterns (not shown) over the top insulating layer stack 220 and performing etching processes to form top via hole patterns 63 and upper bottom via hole patterns 73. The top via hole patterns 63 may be formed in the top via plug region 16, and the upper bottom via hole patterns 73 may be formed in the bottom via plug region 17. Depths of the top via hole patterns 63 may gradually increase in one direction. That is, the top via hole patterns 63 may gradually be deepened in one direction. The top via hole patterns 63 may have different vertical lengths with each other in the top via plug region 16. Lower ends of the top via hole patterns 63 may abut the top sacrificial insulating layers 222 and expose surfaces of corresponding top sacrificial insulating layers 222. That is, each hole pattern formed in the top via plug region 16—each top via hole pattern 63 may be formed to correspond to each top sacrificial insulating layer 222 of the top insulating layer stack 220. The upper bottom via hole patterns 73 may extend to vertically and completely pass through the top insulating layer stack 220 to be vertically aligned with the corresponding sacrificial via plugs 72, respectively. The upper bottom via hole patterns 73 may expose top surfaces of the corresponding sacrificial via plugs 72. The upper via hole patterns 73 may have the same vertical depths in the bottom via plug region 17. In an embodiment, the top via hole patterns 63 and the upper bottom via hole patterns 73 may correspond to the hole patterns H1 to H4 formed in one of the sites Sa-Sh and arranged in a zigzag pattern, respectively. (See FIG. 7) In another embodiment, the top via hole patterns 63 and the upper bottom via hole patterns 73 may correspond to the representative hole patterns Ha-Hh in each of the sites Sa-Sh (see FIG. 15)

Referring to FIG. 20E, the method may further include removing the filling material in the sacrificial via plugs 72 to re-form the lower bottom via hole patterns 71. The lower bottom via hole patterns 71 in the bottom insulating layer stack 120 and the upper bottom via hole patterns 73 in the top insulating layer stack 220 may be vertically aligned with each other and spatially merged, respectively. The lower bottom via hole patterns 71 and the upper bottom via hole patterns 73 may form bottom via hole patterns 74 by being merged, respectively. Therefore, lower ends of the bottom via hole patterns 74 may abut the corresponding bottom sacrificial insulating layers 122, respectively, and expose surfaces of the corresponding bottom sacrificial insulating layers 122.

Referring to FIG. 20F, the method may further include forming top via plugs 60 and bottom via plugs 70 by performing a filling process to fill top via hole patterns 63 and bottom via hole patterns 74, i.e., lower and upper bottom via hole patterns 71 and 73, with a conductor. Each bottom via plug 70 may include each lower bottom via plug 75 and each upper bottom via plug 76 vertically aligned. The lower bottom via plugs 75 may be formed by filling the lower bottom via hole patterns 71 with the conductor, and the upper bottom via plugs 76 may be formed by filling the upper bottom via hole patterns 73 with the conductor. The conductor may include at least one of polycrystalline silicon, a metal, a metal silicide, a metal compound, or a metal alloy. The top via plugs 60 and the bottom via plugs 70 may gradually vertically longer in one direction. The top via plugs 60 and the bottom via plugs 70 may have different vertical lengths with each other in the top via plug region 16 and the bottom via plug region 17.

FIG. 20G is an enlarged view of the area A of FIG. 20F. Referring to FIG. 20G, an interface between the bottom upper insulating layer 124 and the top lower insulating layer 221 and interfaces between the lower bottom via plugs 75 and the upper bottom via plugs 76 may be coplanar and may be positioned at the same level. At the interface between the lower bottom via plugs 75 and the upper bottom via plugs 76, a horizontal width Wb of an upper end of each lower bottom via plug 75 may be greater than a horizontal width Wt of a lower end of each corresponding upper bottom via plug 76. The upper end of the lower bottom via plugs 75 may have a disk-shaped flat portion—e.g., a porch—around the lower end of the upper bottom via plugs 76. The lower bottom via plugs 75 and the upper bottom via plugs 76 may have a pillar shape. Thus, the horizontal widths Wb and Wt may be diameters.

Referring to FIG. 20H, the method may further include forming a capping layer 510 and forming a bottom word line stack 320 and a top word line stack 420 by replacing the bottom sacrificial insulating layers 122 and the top sacrificial insulating layers 222 with bottom word lines 331 and top word lines 431. The capping layer 510 may include a silicon oxide-based insulating layer. The bottom word lines 331 and the top word lines 431 may include a conductor. The conductor may include at least one of polycrystalline silicon, a metal, a metal silicide, a metal compound, or a metal alloy. The top via plugs 60 may be in contact with and electrically connected to the corresponding top word lines 431 of the top word line stack 420, respectively. The bottom via plugs 70 may be in contact with and electrically connected to the corresponding bottom word lines 331 of the bottom word line stack 320, respectively.

Referring to FIG. 20I, the method may further include forming a three-dimensional semiconductor device by forming contact plugs 535 and horizontal wirings 536. The contact plugs 535 may extend to vertically pass through the capping layer 510 to be electrically connected to one of the corresponding top via plugs 60 and bottom via plugs 70, respectively. The horizontal wirings 536 may be formed over the capping layer 510 to be electrically connected to the contact plugs 535, respectively. The contact plugs 535 and the horizontal wirings 536 may include a conductor. The conductor may include at least one of polycrystalline silicon, a metal, a metal silicide, a metal compound, or a metal alloy.

In an embodiment, the three-dimensional semiconductor device may include the bottom word line stack 320, the top word line stack 420, top via plugs 60, and the bottom via plugs 70. The bottom word line stack 320 may include the bottom word lines 331. The top word line stack 430 may include the top word lines 431. The top word line stack 430 may be disposed on the bottom word line stack 320. The bottom via plugs 70 may be vertically longer than the top via plugs 60. The top via plugs 60 may be connected to the top word lines 431, respectively. The bottom via plugs 70 may be connected to the bottom word lines 331, respectively. The bottom via plugs 70 may include upper bottom via plugs 76 extending to vertically pass through the top word line stack 420 and lower bottom via plugs 75 respectively connected to the bottom word lines 331 of the bottom word line stack 320. The upper bottom via plugs 76 may be vertically aligned with and connected to the corresponding lower bottom via plugs 75, respectively. A horizontal width Wb of an upper end of each of the lower bottom via plugs 75 may be greater than a horizontal width Wt of a lower end of each of the upper bottom via plugs 76.

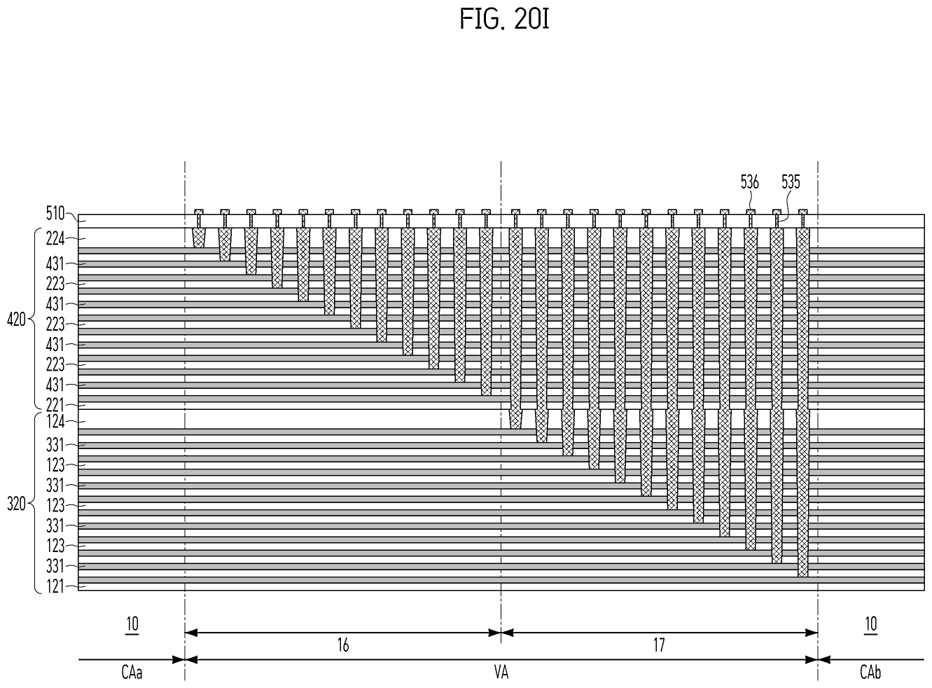

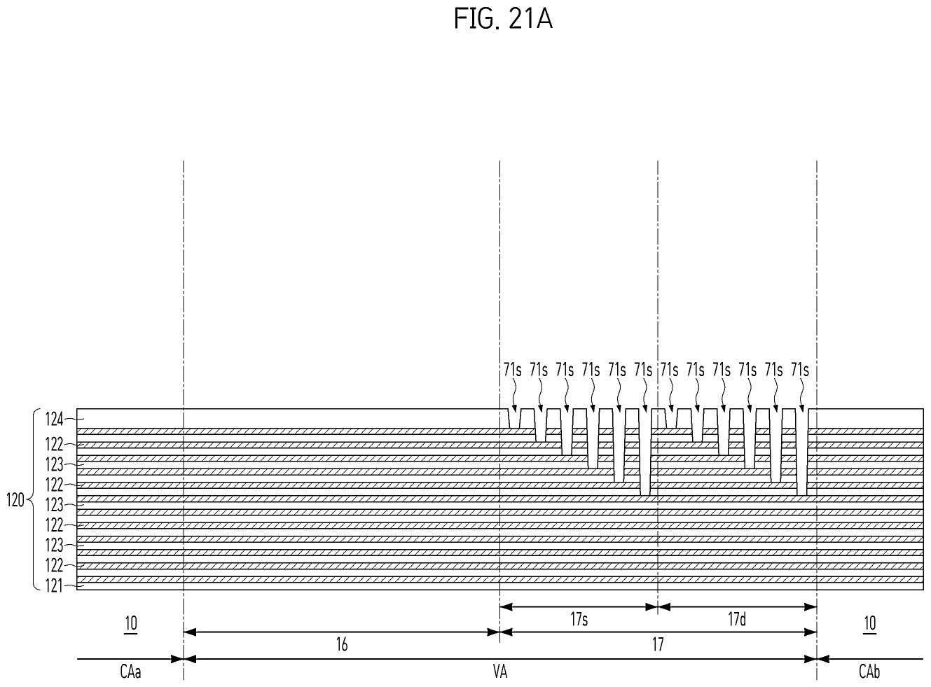

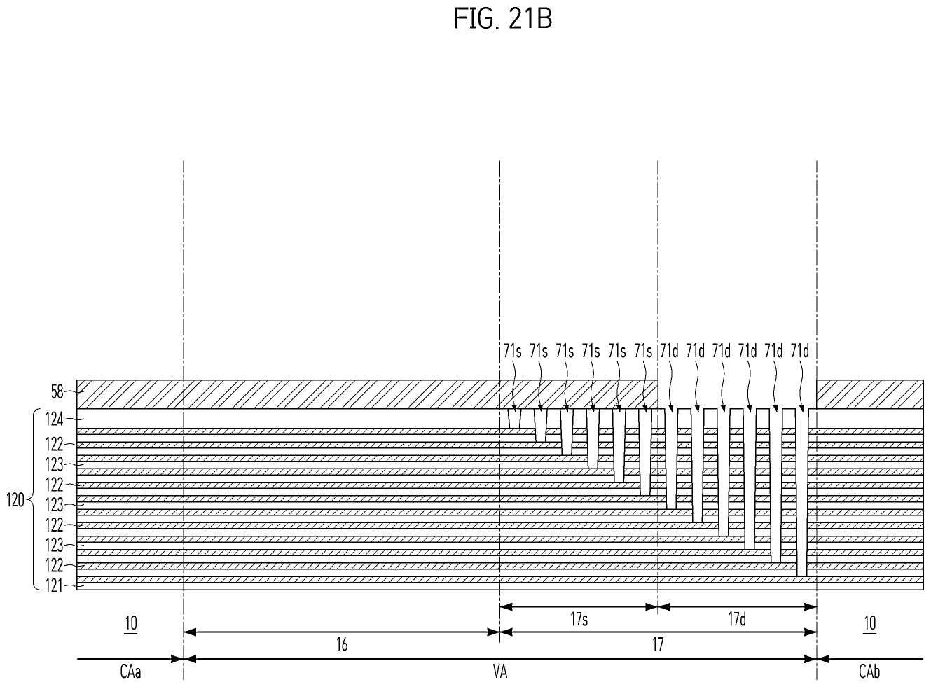

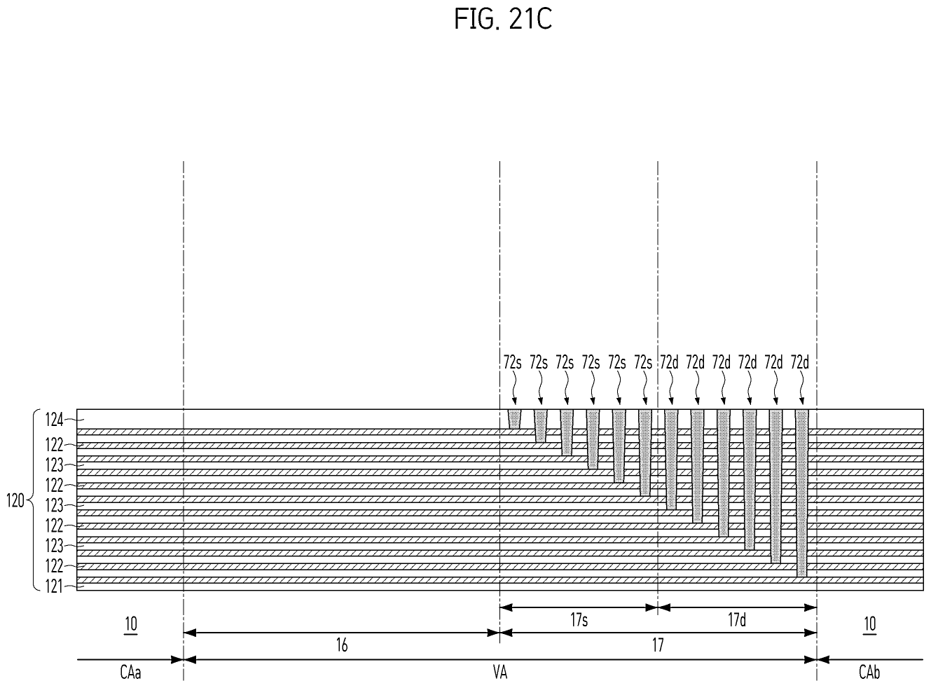

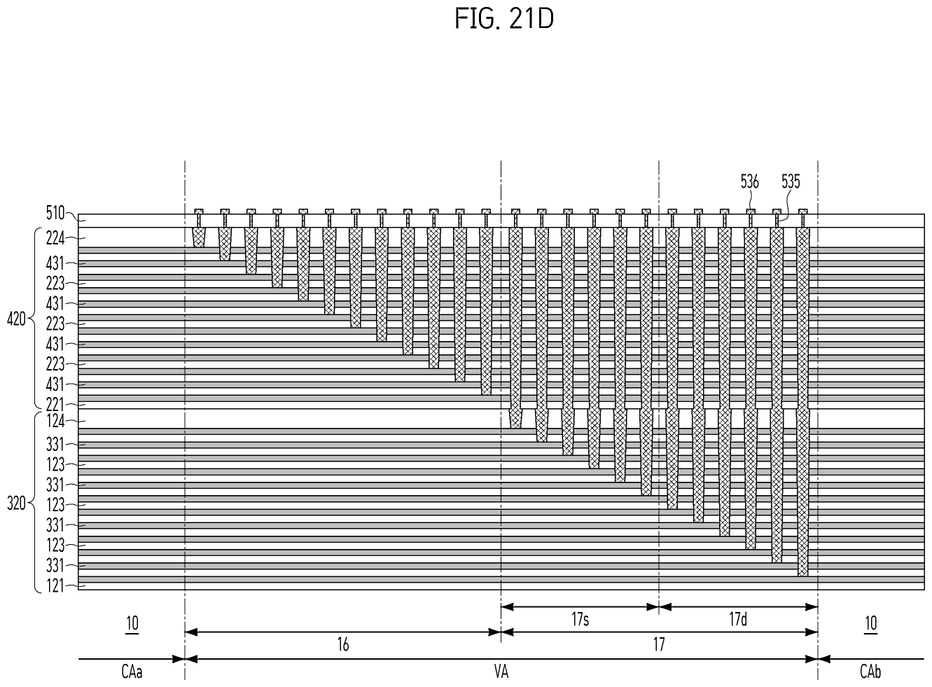

FIGS. 21A to 21D are diagrams illustrating a method of forming a three-dimensional semiconductor device according to an embodiment of the present invention. For example, longitudinal sectional views taken along the lines I-I′ and II-II′ lines of FIG. 1C are overlapped or in side-by-side, but adjacent patterns in the drawings may be spaced apart in a diagonal direction in a plan or top view.

Referring to FIG. 21A, the method may include forming a bottom insulating layer stack 120 over a lower layer 10, forming a bottom hard mask pattern (not shown), bottom photoresist patterns (not shown), and bottom mask patterns (not shown) over the bottom insulating layer stack 120, and performing etching processes to form shallow bottom via hole patterns 71s. The lower layer 10 and the bottom insulating layer stack 120 may include cell regions CAa and CAb and a via plug region VA between cell regions CAa and CAb. The via plug region VA may include a top via plug region 16 and a bottom via plug region 17. The bottom via plug region 17 may include a shallow bottom via plug region 17s and a deep bottom via plug region 17d. In an embodiment, the shallow bottom via plug region 17s and the deep bottom via plug region 17d may be different from each other among the sites Sa-Sh. The shallow bottom via hole patterns 71s may be formed in the shallow bottom via plug region 17s and the deep bottom via plug region 17d. For example, referring to FIG. 7, the same arrangement and the same shape of shallow bottom via hole patterns 71s may be formed in different regions 17s and 17d. That is, one of the shallow bottom via hole patterns 71s formed in the shallow bottom via plug region 17s and one of the shallow bottom via hole patterns 71s formed in the deep bottom via plug region 17d may include shallow bottom via hole pattern pairs having the same depth. (See FIGS. 4 to 7) The shallow bottom via hole patterns 71s may be arranged in a zigzag pattern and may have different depths with each other in each of the regions 17s and 17d. That is, the shallow bottom via hole patterns 71s may be formed to have different depths in the shallow bottom via plug region 17s, and the shallow bottom via hole patterns 71s may be formed to have different depths in the deep bottom via plug region 17d.

Referring to FIG. 21B, the method may further include forming a mask pattern 58 covering the top via plug region 16 and the shallow bottom via plug region 17s and opening the deep bottom via plug region 17d, and forming the lower deep bottom via hole patterns 71d in the deep bottom via plug region 17d by performing an etching process to be deepened the shallow bottom via hole patterns 71. The shallow lower bottom via hole patterns 71s in the deep bottom via plug region 17d of FIG. 21A may extend and be deepened by an etching process, and may be formed as lower deep bottom via hole patterns 71d. Thereafter, the method may further include removing the mask pattern 58.

Referring to FIG. 21C, the method may further include forming sacrificial via plugs 72s and 72d by performing a filling process to fill the shallow bottom via hole patterns 71s and the lower deep bottom via hole patterns 71d with a filling material. The sacrificial via plugs 72s and 72d may include shallow sacrificial via plugs 72s formed in the shallow bottom via plug region 17s and deep sacrificial via plugs 72d formed in the deep bottom via plug region 17d. The deep sacrificial via plugs 72d may be vertically longer than the shallow sacrificial via plugs 72s. For example, the shortest one of the deep sacrificial via plugs 72d may be vertically longer than the longest one of the shallow sacrificial via plugs 72s.

Referring to FIG. 21D, the method may further include forming a three-dimensional semiconductor device by performing the processes described with reference to FIGS. 20C to 201. Elements and reference numerals that are not described will be understood with reference to FIGS. 20C to 201.

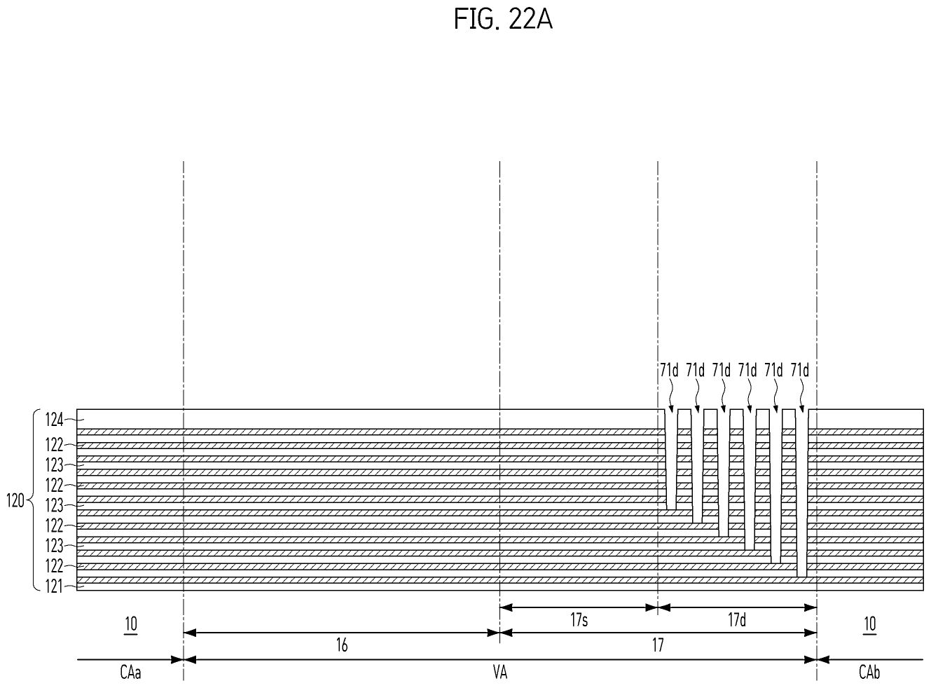

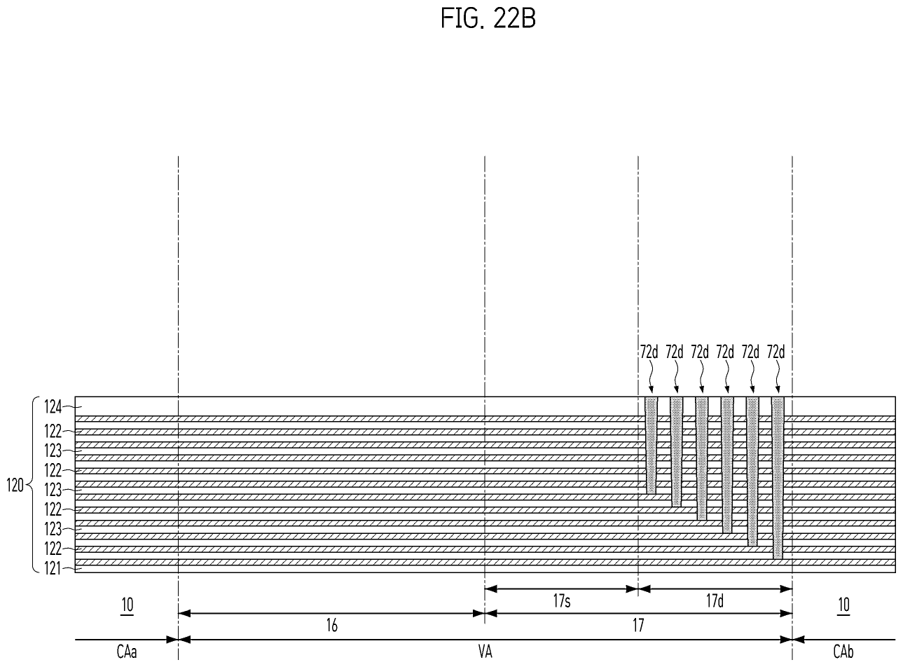

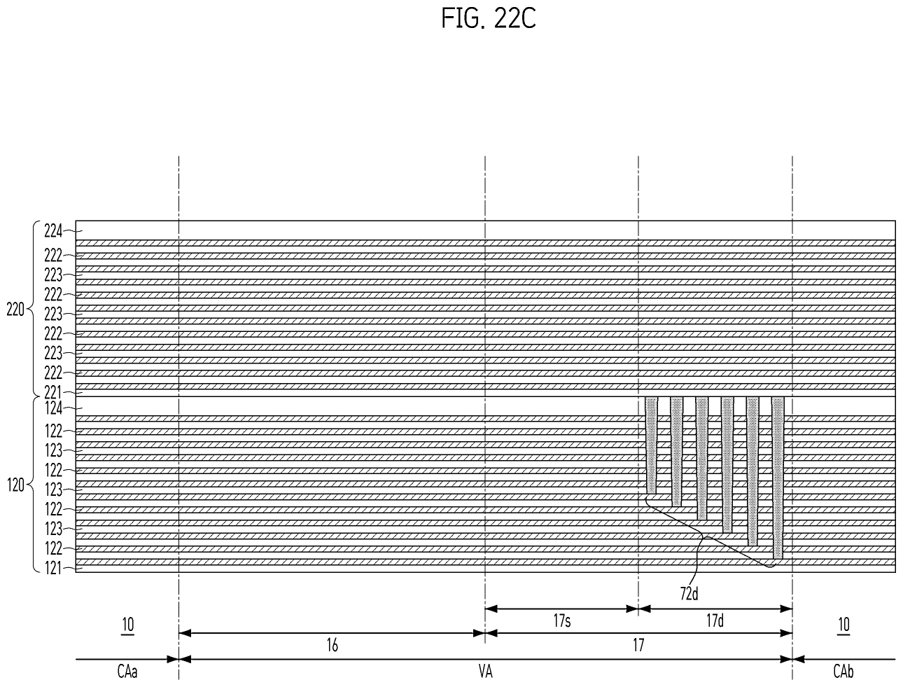

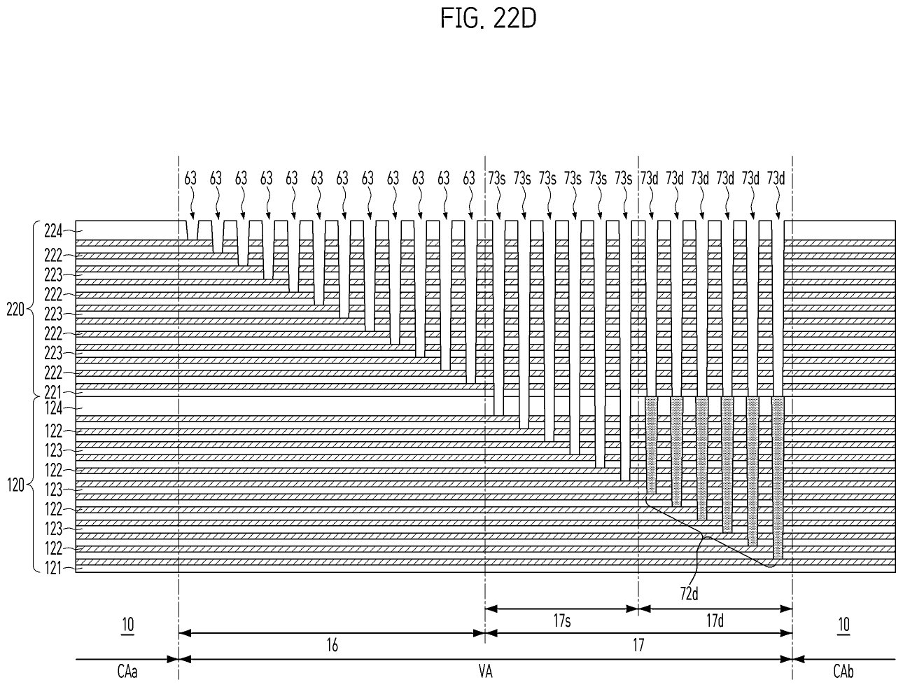

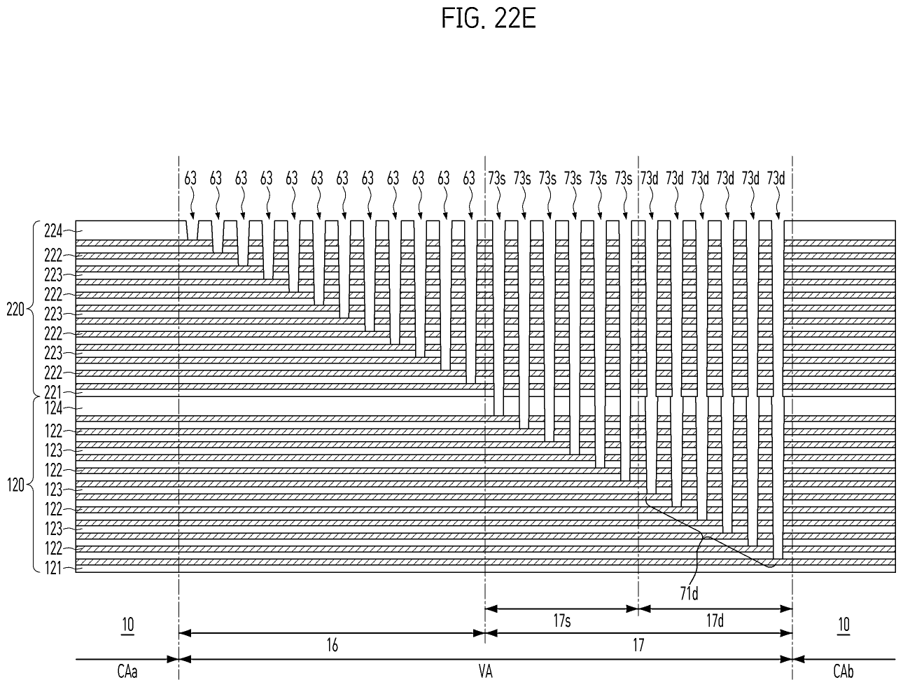

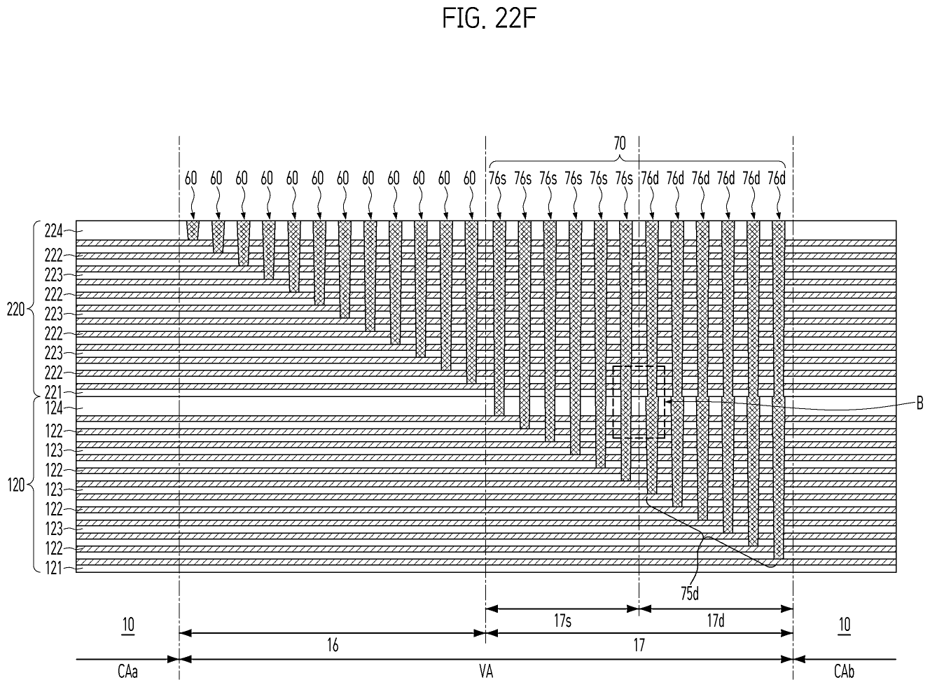

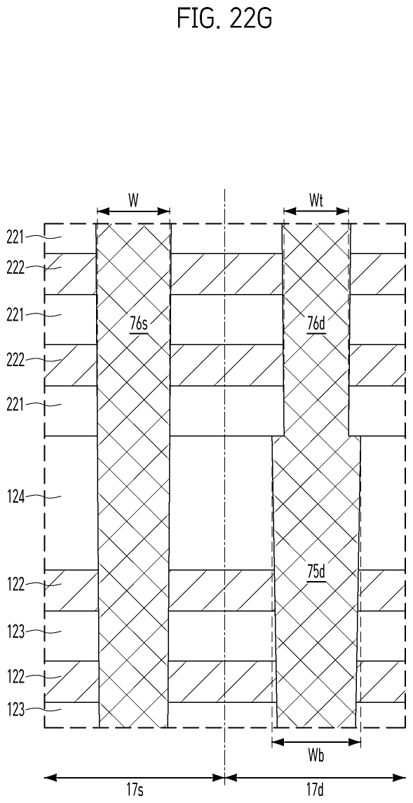

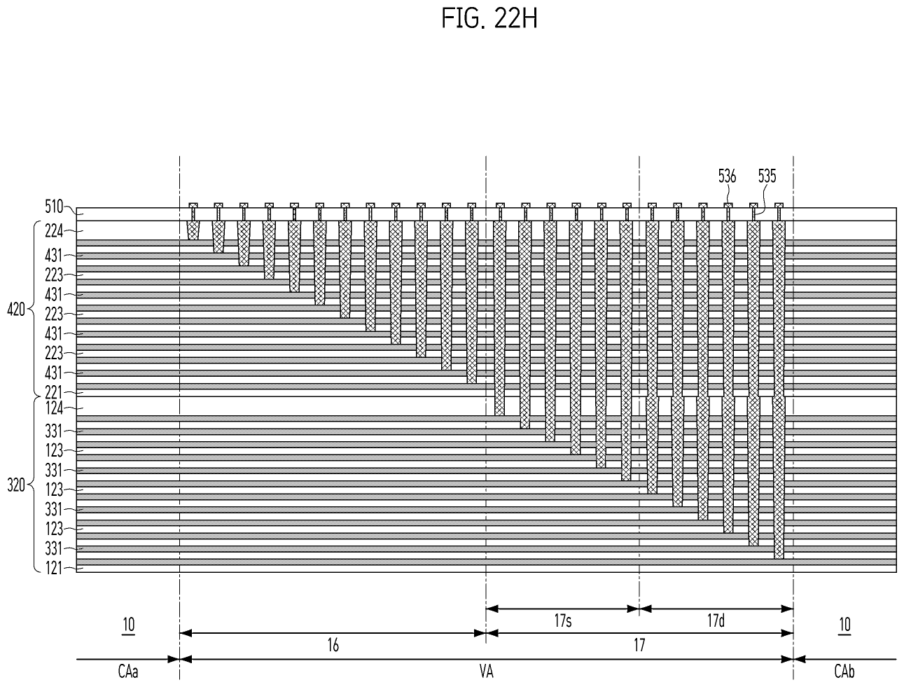

FIGS. 22A to 221 are diagrams illustrating a method of forming a three-dimensional semiconductor device according to an embodiment of the present invention. For example, longitudinal sectional views taken along the lined I-I′ and II-II′ of FIG. 1C are overlapped or in a side-by-side, but adjacent patterns in the drawings may be spaced apart in a diagonal direction in a plan or top view

Referring to FIG. 22A, the method may include forming a bottom insulating layer stack 120 over a lower layer 10 with reference to FIGS. 3A to 7, forming a bottom hard mask pattern (not shown), bottom photoresist patterns (not shown), and bottom mask patterns (not shown) on the bottom insulating layer stack 120, and performing etching processes to form bottom deep via hole patterns 71d in the deep bottom via plug region 17d. The lower deep bottom via hole patterns 71d may not be formed in the shallow bottom via plug region 17s. Compared with FIG. 21A, the lower shallow bottom via hole patterns 71s may not be formed in the shallow bottom via plug region 17s.

Referring to FIG. 22B, the method may further include forming deep sacrificial via plugs 72d by performing a filling process to fill the lower deep bottom via hole patterns 71d with a filling material. The deep sacrificial via plugs 72d may be formed only in the deep bottom via plug region 17d.

Referring to FIG. 22C, the method may further include forming a top insulating layer stack 220 over the bottom insulating layer stack 120. Forming the top insulating layer stack 220 may include forming a top lower insulating layer 221, top sacrificial insulating layers 222, top interlayer insulating layers 223, and a top upper insulating layer 224 by performing deposition processes.

Referring to FIG. 22D, the method may include forming a top hard mask pattern (not shown), top photoresist patterns (not shown), and top mask patterns (not shown) over the top insulating layer stack 220 and performing etching processes to form top via hole patterns 63 and upper bottom via hole patterns 73s and 73d. The upper bottom via hole patterns 73s and 73d may include shallow bottom via hole patterns 73s formed in the shallow bottom via plug region 17s and upper deep bottom via hole patterns 73d formed in the deep bottom via plug region 17d. The shallow bottom via hole patterns 73s may extend to inside the bottom insulating layer stack 120 by vertically passing through the top insulating layer stack 220. Lower ends of the shallow bottom via hole patterns 73s may be abut the corresponding bottom sacrificial insulating layers 122 of the bottom insulating layer stack 120 and may expose surfaces of the corresponding bottom sacrificial insulating layers 122. The upper deep bottom via hole patterns 73d may be vertically aligned with corresponding deep sacrificial via plugs 72d, respectively. The upper deep bottom via hole patterns 73d may expose top surfaces of the corresponding deep sacrificial via plugs 72d, respectively. An interface between the bottom upper insulating layer 124 and the top lower insulating layer 221 and interfaces between the deep sacrificial via plugs 72d and the upper deep bottom via hole patterns 73d may be coplanar and may be positioned at the same level. At the interface between the bottom upper insulating layer 124 and the top lower insulating layer 221, sidewalls of the shallow bottom via hole patterns 73s may be flat in a vertical or tilted direction. In an embodiment, the top via hole patterns 63 and the upper bottom via hole patterns 73s and 73d may correspond to the hole patterns H1 to H4 formed in one of the sites Sa-Sh and arranged in a zigzag pattern, respectively. (See FIG. 7) In another embodiment, the top via hole patterns 63 and the upper bottom via hole patterns 73s and 73d may correspond to the representative hole patterns Ha-Hh in each of the sites Sa-Sh (see FIG. 15)

Referring to FIG. 22E, the method may further include removing the filling material in the deep sacrificial via plugs 72d. The deep sacrificial via plugs 72d may be re-formed to the lower deep bottom via hole patterns 71d. An interface between the bottom upper insulating layer 124 and the top lower insulating layer 221 and interfaces between the lower deep bottom via hole patterns 71d and the upper deep bottom via hole patterns 73d may be coplanar and may be positioned at the same level.

Referring to FIG. 22F, the method may further include performing a deposition or filling process to form top via plugs 60 and bottom via plugs 70 by filling the top via hole patterns 63 and the lower and upper bottom via hole patterns 71d, 73s, and 73d with a conductor. The bottom via plugs 70 may include upper shallow bottom via plugs 76s formed in the shallow bottom via plug region 17s, upper deep bottom via plugs 76d and lower deep bottom via plugs 75d formed in the deep bottom via plug region 17d. Each of the upper deep bottom via plugs 76d may be vertically aligned with and be electrically connected to each of the lower deep bottom via plugs 75d.

FIG. 22G is an enlarged view of the area B of FIG. 22F. Referring to FIG. 20G, an interface between the bottom upper insulating layer 124 and the top lower insulating layer 221 and interfaces between the lower deep bottom via plugs 75d and the upper deep bottom via plugs 76d may be coplanar and may be positioned at the same level. In the deep bottom via plug region 17d, at the interfaces between the lower deep bottom via plugs 75d and the upper deep bottom via plugs 76d, a horizontal width Wb of an upper end of each lower deep bottom via plug 75d may be greater than a horizontal width Wt of a lower end of each corresponding upper deep bottom via plug 76d. In the shallow bottom via plug region 17s, side surfaces of the upper shallow bottom via plugs 76s may be flat in a vertical or tilted direction at the interface between the bottom upper insulating layer 124 and the top lower insulating layer 221.

At the interface between the bottom upper insulating layer 124 and the top lower insulating layer 221, a horizontal width W of the upper shallow bottom via plugs 76s may be smaller than the horizontal width Wb of the upper end of the lower deep bottom via plugs 75d.

Referring to FIG. 22H, the method may further include forming a three-dimensional semiconductor device by performing the processes described with reference to FIGS. 20H and 201.

Although the technical features of the present disclosure have been specifically recorded according to the above embodiments, it should be noted that the above embodiments are for the purpose of explanation and not for the limitation of the present disclosure. In addition, it will be appreciated by one of ordinary skill in the art that various changes and modifications can be made thereto without departing from the scope of the disclosure.

What is claimed is:

1. A three-dimensional semiconductor device comprising:
a lower layer with a top via plug region, a shallow bottom via plug region, and a deep bottom via plug region;
a bottom word line stack stacked over the lower layer;
a top word line stack stacked over the bottom word line stack, wherein the top word line stack includes top word lines and top interlayer insulating layers alternately stacked;
top via plugs extending vertically through the top word line stack in the top via plug region;
upper deep bottom via plugs extending vertically and completely through the top word line stack; and
lower deep bottom via plugs extending vertically and partially through the bottom word line stack,
wherein the bottom word line stack includes a bottom lower insulating layer, a bottom upper insulating layer, bottom word lines and bottom interlayer insulating layers alternately stacked between the bottom lower insulating layer and the bottom upper insulating layer,
wherein the top word line stack includes a top lower insulating layer, a top upper insulating layer, top word lines and top interlayer insulating layers alternately stacked between the top lower insulating layer and the top upper insulating layer,
wherein the top via plugs are electrically connected to the top word lines, respectively,
wherein the upper deep bottom via plugs and the lower deep bottom via plugs are vertically aligned with each other, respectively,
wherein a lower end of each of the lower deep bottom via plugs is electrically connected to each of the bottom word lines, respectively,
wherein a horizontal width of an upper end of each of the lower deep bottom via plugs is greater than a horizontal width of a lower end of each of the upper deep bottom via plugs.

2. The three-dimensional semiconductor device of claim 1,
wherein the top via plugs, the lower deep bottom via plugs, and the upper deep bottom via plugs each are arranged in a zigzag pattern in a top view.

3. The three-dimensional semiconductor device of claim 1, further comprising:
upper shallow bottom via plugs extending vertically and completely through the top word line stack in the shallow bottom via plug region; and
lower shallow bottom via plugs extending vertically and partially through the bottom word line stack in the shallow bottom via plug region,
wherein the upper shallow bottom via plugs and the lower shallow bottom via plugs are vertically aligned with each other, respectively,
wherein lower ends of the lower shallow bottom via plugs are electrically connected to the bottom word lines, respectively, and
wherein a horizontal width of an upper end of each of the lower shallow bottom via plugs is greater than a horizontal width of a lower end of each of the upper shallow bottom via plugs.

4. The three-dimensional semiconductor device of claim 3,
wherein an interface between the bottom upper insulating layer of the bottom word line stack and the top lower insulating layer of the top word line stack, interfaces of the lower deep bottom via plugs and the upper deep bottom via plugs, and interfaces of the lower shallow bottom via plugs and the upper shallow bottom via plugs are located at a same level.

5. The three-dimensional semiconductor device of claim 4,
wherein the top via plugs have different vertical lengths with each other in the top via plug region,
wherein the upper shallow bottom via plugs have a same vertical length with each other in the shallow bottom via plug region,
wherein the lower shallow bottom via plugs have different vertical lengths with each other in the shallow bottom via plug region,
wherein the upper deep bottom via plugs have a same vertical length with each other in the deep bottom via plug region, and
wherein the lower deep bottom via plugs have different vertical lengths with each other in the deep bottom via plug region.

6. The three-dimensional semiconductor device of claim 1, further comprising:
upper shallow bottom via plugs extending vertically and completely through the top word line stack and partially through the bottom word line stack in the shallow bottom via plug region, and
wherein each of the upper shallow bottom via plugs is electrically connected to a corresponding one of the bottom word lines.

7. The three-dimensional semiconductor device of claim 6,
wherein an interface between the bottom upper insulating layer of the bottom word line stack and the top lower insulating layer of the top word line stack, and interfaces of the lower deep bottom via plugs and the upper deep bottom via plugs are located at a same level, and
sidewalls of the upper shallow via plug are flat at the level.

8. The three-dimensional semiconductor device of claim 7,
wherein the top via plugs have different vertical lengths with each other in the top via plug region,
wherein the upper shallow bottom via plugs have different vertical lengths with each other in the shallow bottom via plug region,
wherein the upper deep bottom via plugs have a same vertical length with each other in the deep bottom via plug region, and
wherein the lower deep bottom via plugs have different vertical lengths with each other in the deep bottom via plug region.

9. The three-dimensional semiconductor device of claim 1,
wherein the lower layer includes a first cell region, a second cell region, and a via plug region positioned between the first cell region and the second cell region,
wherein the via plug region includes the top via plug region, the shallow bottom via plug region, and the deep bottom via plug region, and
wherein the bottom word line stack and the top word line stack extend horizontally to the first cell region, the via plug region, and the second cell region to be commonly connected to first memory cells in the first cell region and second memory cells in the second cell region, respectively.

10. The three-dimensional semiconductor device of claim 9,
wherein the via plug region includes a plurality of sites having at least four via plugs, and
wherein the top via plug region, the shallow bottom via plug region, and the deep bottom via plug region are each one of the plurality of sites.

11. The three-dimensional semiconductor device of claim 1,
wherein the top via plugs have different vertical lengths with each other in the top via plug region,
wherein the upper deep bottom via plugs have a same vertical length with each other in the deep bottom via plug region, and
wherein the lower deep bottom via plugs have different vertical lengths with each other in the deep bottom via plug region.

12. A three-dimensional semiconductor device comprising:
a bottom word line stack with a top via plug region and a bottom via plug region, and a top word line stack over the bottom word line stack;
top via plugs disposed in the top via plug region; and
bottom via plugs disposed in the bottom via plug region,
wherein the bottom via plugs include:
upper bottom via plugs extending vertically and completely through the top word line stack; and
lower bottom via plugs extending vertically and partially through the bottom word line stack,
wherein an interface between the bottom word line stack and the top word line stack and interfaces of the lower bottom via plugs and the upper bottom via plugs are located at a same level,
wherein a horizontal width of an upper end of each of the lower bottom via plugs is greater than a horizontal width of a lower end of each of the upper bottom via plugs at the interface between the bottom word line stack and the top word line stack.

13. The three-dimensional semiconductor device of claim 12,
wherein the top via plugs in the top via plug region and the bottom via plugs in the bottom via plug region are arranged in a zigzag pattern, respectively.

14. The three-dimensional semiconductor device of claim 12,
wherein the top via plugs have different vertical lengths with each other in the top via plug region, and
wherein the bottom via plugs have different vertical lengths with each other in the bottom via plug region.

15. The three-dimensional semiconductor device of claim 12,
wherein the bottom via plug region includes a shallow bottom via plug region and a deep bottom via plug region,
wherein the bottom via plugs include shallow bottom via plugs disposed in the shallow bottom via plug region,
wherein the shallow bottom via plugs include:
upper shallow bottom via plugs extending vertically and completely through the top word line stack; and
lower shallow bottom via plugs extending vertically and partially through the bottom word line stack,
wherein an interface between the bottom word line stack and the top word line stack, and interfaces between the lower shallow bottom via plugs and the upper shallow bottom via plugs are located at a same level, and
wherein a horizontal width of an upper end of each of the lower shallow bottom via plugs is greater than a horizontal width of a lower end of each of the upper shallow bottom via plugs.

16. The three-dimensional semiconductor device of claim 15, in the shallow bottom via plug region,
wherein the upper shallow bottom via plugs have a same vertical length with each other, and
wherein the lower shallow bottom via plugs have different vertical lengths.

17. The three-dimensional semiconductor device of claim 12,
wherein the bottom via plug region includes a shallow bottom via plug region and a deep bottom via plug region,
wherein the bottom via plugs further include shallow bottom via plugs disposed in the shallow bottom via plug region,
wherein the shallow bottom via plugs vertically and completely pass through the top word line stack and partially vertically pass through the bottom word line stack,
wherein sidewalls of the shallow bottom via plugs are flat at the interface between the bottom word line stack and the top word line stack.

18. The three-dimensional semiconductor device of claim 17,
wherein the shallow bottom via plugs have different vertical lengths with each other in the shallow bottom via plug region.

19. The three-dimensional semiconductor device of claim 12,
wherein the bottom word line stack and the top word line stack include a first cell region, a second cell region, and a via plug region between the first cell region and the second cell region,
wherein the via plug region includes the top via plug region and the bottom via plug region,
wherein the bottom word line stack and the top word line stack extend horizontally to the first cell region and the second cell region to be commonly connected to first memory cells in the first cell region and second memory cells in the second cell region, respectively.
